(19) United States
(12) Patent Application Publication
(10) Pub. No.: US 2023/0089435 A1
(43) Pub. Date: Mar. 23, 2023

(54) DISPLAY DEVICE AND MANUFACTURING METHOD THEREFOR

(71) Applicant: Samsung Display Co., LTD., Yongin-si, Gyeonggi-do (KR)

(72) Inventor: Yong Woon LIM, Seoul (KR)

(73) Assignee: Samsung Display Co., LTD., Yongin-si, Gyeonggi-do (KR)

(21) Appl. No.: 17/909,277

(22) PCT Filed: Jun. 5, 2020
(86) PCT No.: PCT/KR2020/007346

§ 371 Date: Sep. 2, 2022

(30) Foreign Application Priority Data
Mar. 3, 2020 (KR) 10-2020-0026396

(51) Int. Cl. H01L 33/38; H01L 25/075; H01L 33/62; H01L 33/00

(52) U.S. Cl. CPC H01L 33/387; H01L 25/0753; H01L 33/62; H01L 33/005; H01L 2933/0016; H01L 2933/0066

(57) ABSTRACT

Provided are a display device and a manufacturing method therefor. The display device includes: a first substrate; a first electrode and a second electrode spaced apart from each other on the first substrate; a plurality of light emitting elements at least a portion of which is arranged between the first electrode and the second electrode; a first contact electrode at least partially covering the first electrode and contacting one end of each of the light emitting elements; and a second contact electrode spaced apart from the first contact electrode to at least partially cover the second electrode and contacting the other end of each of the light emitting elements, wherein the first contact electrode and the second contact electrode comprise a conductive polymer.

### CROSS REFERENCE TO RELATED APPLICATION(S)

This application is a national entry of International Application No. PCT/KR2020/007346, filed on Jun. 5, 2020, which claims under 35 U.S.C. §§ 119(a) and 365(b) priority to and benefits of Korean Patent Application No. 10-2020-0026396, filed on Mar. 3, 2020, in the Korean Intellectual Property Office (KIPO), the entire content of which are incorporated herein by reference.

### BACKGROUND

### 1. Technical Field

The disclosure relates to a display device and a manufacturing method thereof.

### 2. Description of Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

An aspect of the disclosure is to provide a display device including a light emitting element and a contact electrode electrically connected to the light emitting element and including conductive polymer.

Another aspect of the disclosure is to provide a method of manufacturing a display device with reduced processes.

The aspect of the disclosure is not limited to those set forth herein, and other aspect of the disclosure will become apparent to one of ordinary skilled in the art by referencing the detailed description of the disclosure given below.

To address the aforementioned problems, embodiments of the disclosure provide a display device including light emitting elements and contact electrodes, which are electrically connected to the light emitting elements and include conductive polymer.

Embodiments of the disclosure also provide a method of manufacturing a display device, which can shorten the fabrication of a display device.

It should be noted that aspects of the disclosure are not limited thereto and other aspects, which are not mentioned herein, will be apparent to those of ordinary skill in the art from the following description.

### SUMMARY

According to an embodiment of the disclosure, a display device may include a first electrode and a second electrode disposed on a substrate and spaced apart from each other, a plurality of light emitting elements, at least a part of each of the plurality of light emitting elements being disposed between the first electrode and the second electrode, a first contact electrode at least partially covering the first electrode, the first contact electrode electrically contacting first end portions of the plurality of light emitting elements, and a second contact electrode spaced apart from the first contact electrode and at least partially covering the second electrode, the second contact electrode electrically contacting second end portions of the plurality of light emitting elements. The first contact electrode and the second contact electrode may include conductive polymer.

The conductive polymer may include PEDOT:PSS.

Each of the first contact electrode and the second contact electrode may have a thickness in a range of about 150 nm to about 250 nm.

The first contact electrode and the second contact electrode may be spaced apart from each other on the plurality of light emitting elements.

The display device may further include a plurality of first banks disposed between the first electrode and the substrate and between the second electrode and the substrate, middle portions of the plurality of first banks being thicker than a rest of the plurality of first banks in a thickness direction. The first contact electrode and the second contact electrode may be disposed to at least partially overlap one of the plurality of first banks in the thickness direction.

The first contact electrode may be disposed to overlap one of the plurality of first banks in the thickness direction, the second contact electrode may be disposed to overlap another one of the plurality of first banks in the thickness direction. A portion of the first contact electrode that overlaps one of the thicker portion of the plurality of first banks may be thicker than a rest of the first contact electrode, and a portion of the second contact electrode that overlap another one of the thick portions of the plurality of first banks may be thicker than a rest of the second contact electrode.

Portions of the first contact electrode and the second contact electrode that cover the first end portions of the light emitting elements may be thicker than the rest of the first contact electrode and the second contact electrode.

The plurality of light emitting elements may include first light emitting elements including first end portions electrically contacting the first contact electrode and second end portions electrically contacting the second contact electrode and second light emitting elements which are disposed on the first light emitting elements and including first end portions electrically contacting the first contact electrode and second end portions electrically contacting the second contact electrode.

The display device may further include a first insulating layer disposed on the substrate between the first electrode and the second electrode, partially covering the first electrode and the second electrode. The plurality of light emitting elements may be disposed on the first insulating layer.

The display device may further include a second insulating layer disposed on the substrate covering the first electrode, the second electrode, the plurality of light emitting elements, the first contact electrode, and the second contact electrode.

The second insulating layer may be directly contacting portions of outer surfaces of the plurality of light emitting elements, and the first contact electrode and the second contact electrode are spaced apart from each other with the portions of the outer surfaces of the plurality of light emitting elements disposed between the first and second contact electrodes.

The display device may further include a second bank disposed on the substrate surrounding a region where the plurality of light emitting elements are disposed. The second insulating layer may be disposed on the second bank.

According to an embodiment of the disclosure, a method of manufacturing a display device may include preparing a substrate and disposing a first electrode and a second electrode on the substrate, spraying ink including a plurality of light emitting elements, liquid crystal molecules, and conductive polymer onto the substrate, and forming a plurality of contact electrodes disposed on the first electrode and the second electrode by aligning the liquid crystal molecules and the plurality of light emitting elements by generating an electric field on the substrate and curing the conductive polymer.

The plurality of light emitting elements and the liquid crystal molecules may extend in a first direction. The forming of the plurality of contact electrodes may include aligning the plurality of light emitting elements and the liquid crystal molecules such that the first direction in which the plurality of light emitting elements and the liquid crystal molecules extend may be parallel to an upper surface of the substrate.

The liquid crystal molecules may have positive dielectric anisotropy.

The conductive polymer may be aligned by the electric field such that a main chain portion thereof may be aligned in a second direction and may agglomerate on the first electrode and the second electrode. Both end portions of the plurality of light emitting elements may be fixed by the conductive polymer, aligned in the second direction.

The conductive polymer may include PEDOT:PSS.

The curing of the conductive polymer may be performed by applying light while the plurality of light emitting elements and the liquid crystal molecules are aligned in the second direction.

The plurality of light emitting elements may include first light emitting elements including first end portions disposed on the first electrode and second end portions disposed on the second electrode and second light emitting elements which are disposed on the first light emitting elements and including first end portions disposed on the first electrode and second end portions disposed on the second electrode.

The plurality of contact electrodes may include a first contact electrode electrically contacting first end portions of the plurality of light emitting elements and the first electrode, and a second contact electrode electrically contacting second end portions of the plurality of light emitting elements and the second electrode. The second contact electrode may be spaced apart from the first contact electrode.

The details of other embodiments are included in the detailed description and the accompanying drawings.

According to embodiments, a display device may include contact electrodes, which are electrically connected to a plurality of electrodes and light emitting elements and include conductive polymer. The contact electrodes may include a transparent conductive material (e.g., polymer), and light emitted from the light emitting elements may be reflected by the electrodes through the contact electrodes and may thus be emitted in an upward direction of a substrate.

Also, a method of manufacturing a display device may include spraying ink including light emitting elements, liquid crystal molecules, and conductive polymer dispersed therein onto electrodes and aligning light emitting elements by generating an electric field on the electrodes. The light emitting elements may be aligned in the ink together with the liquid crystal molecules, and the conductive polymer may fix the light emitting elements. Accordingly, the number of fabrication processes for the display device may be reduced, and the degree of alignment of the light emitting elements may be further improved.

The effects according to the embodiments are not limited by the contents above, and more various effects are included in this disclosure.

### BRIEF DESCRIPTION OF DRAWINGS

FIG. 1 is a plan view of a display device according to an embodiment of the disclosure;

FIG. 2 is a plan view of a pixel of the display device according to an embodiment of the disclosure;

FIG. 3 is a schematic cross-sectional view taken along lines IIIa-IIIa′, IIIb-IIIb′, and IIIc-IIIc′ of FIG. 2;

FIG. 4 is an enlarged schematic cross-sectional view of part A of FIG. 3;

FIG. 5 is a schematic view of a light emitting element according to an embodiment of the disclosure;

FIG. 6 is a flowchart illustrating a method of manufacturing a display device according to an embodiment of the disclosure;

FIGS. 7 through 12 are schematic cross-sectional views illustrating the method of manufacturing a display device according to an embodiment of the disclosure;

FIG. 13 is a plan view of a subpixel of a display device according to another embodiment of the disclosure;

FIG. 14 is a plan view of a subpixel of a display device according to another embodiment of the disclosure;

FIG. 15 is a plan view of a subpixel of a display device according to another embodiment of the disclosure;

FIG. 16 is a schematic cross-sectional view taken along line VI-VI′ of FIG. 15;

FIG. 17 is a plan view of a subpixel of a display device according to another embodiment of the disclosure;

FIG. 18 is a schematic cross-sectional view taken along line VIII-VIII′ of FIG. 17;

FIG. 19 is a plan view of a subpixel of a display device according to another embodiment of the disclosure; and

FIG. 20 is a plan view of a subpixel of a display device according to another embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the phrase “at least one of” is intended to include the meaning of “at least one selected from the group of” for the purpose of its meaning and interpretation. For example, “at least one of A and B” may be understood to mean “A, B, or A and B.” As used herein, the term “and/or” includes any and all combinations of one or more of the associated listed items.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

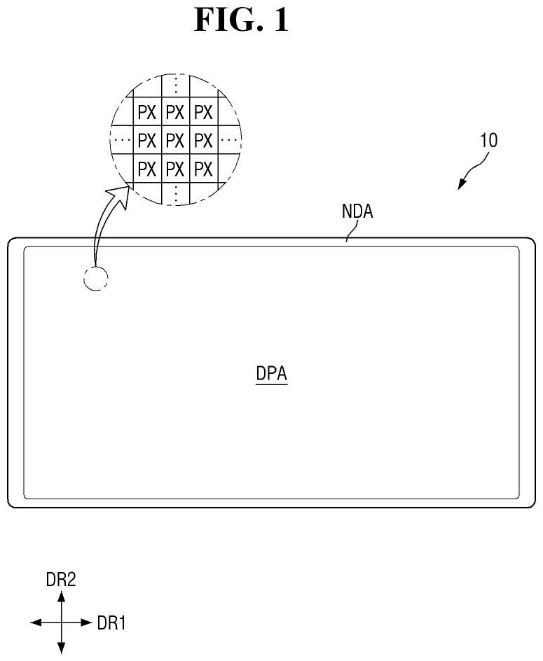

FIG. 1 is a plan view of a display device according to an embodiment of the disclosure.

Referring to FIG. 1, a display device 10 may display a moving or still image. The display device 10 may include nearly all types of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 may include a display panel that provides a display screen. Examples of the display panel of the display device 10 may include an inorganic light-emitting diode (ILED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described including, for example, an ILED display panel, but the disclosure is not limited thereto. For example, various other display panels may be also applicable to the display panel of the display device 10.

The shape of the display device 10 may vary. For example, the display device 10 may have a rectangular shape that extends longer in a horizontal direction than in a vertical direction, a rectangular shape that extends longer in the vertical direction than in the horizontal direction, a square shape, a tetragonal shape with rounded corners, a non-tetragonal polygonal shape, or a circular shape. The shape of a display area DPA of the display device 10 may be similar to the shape of the display device 10. FIG. 1 illustrates an embodiment that the display device 10 and the display area DPA both have a rectangular shape that extends longer in a horizontal direction.

The display device 10 may include the display area DPA and a non-display area NDA. The display area DPA may be an area in which a screen is displayed, and the non-display area NDA may be an area in which a screen is not displayed. The display area DPA may be referred to as an active area, and the non-display area NDA may be referred to as an inactive area. The display area DPA may occupy the middle part of the display device 10.

The display area DPA may include multiple pixels PX. The pixels PX may be arranged in row and column directions. Each of the pixels PX may have a rectangular or square shape in a plan view, but the disclosure is not limited thereto. In another embodiment, each of the pixels PX may have a rhombus shape having sides inclined with respect to a particular direction. In another embodiment, pixels PX may be arranged in stripe or in PenTile™. Each of the pixels PX may include one or more light emitting elements 30, which emit light of a particular wavelength range.

The non-display area NDA may be disposed adjacent to the display area DPA. The non-display area NDA may surround the entire display area DPA or part of the display area DPA. The display area DPA may have a rectangular shape, and the non-display area NDA may be disposed adjacent to four sides of the display area DPA. The non-display area NDA may form a bezel of the display device 10. Lines or circuit drivers included in the display device 10 may be disposed in the non-display area NDA, or external devices may be connected to the non-display area NDA.

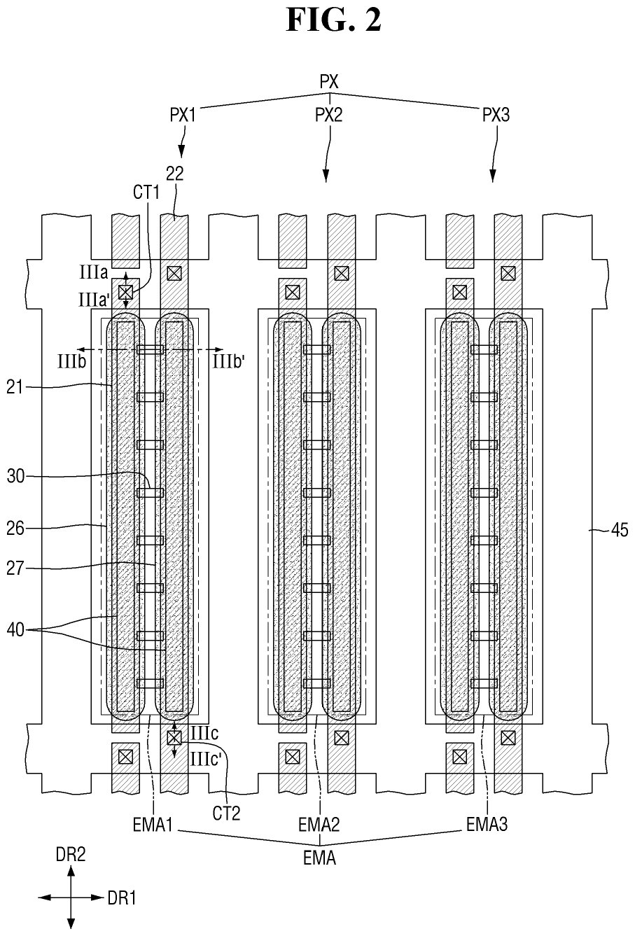

FIG. 2 is a plan view of a pixel of the display device according to an embodiment of the disclosure.

Referring to FIG. 2, each of the pixels PX may include multiple subpixels PXn (where n is an integer of 1 to 3). For example, a pixel PX may include first, second, and third subpixels PX1, PX2, and PX3. The first subpixel PX1 may emit first-color light, the second subpixel PX2 may emit second-color light, and the third subpixel PX3 may emit third-color light. The first-color light, the second-color light, and the third-color light may be blue light, green light, and red light, respectively, but the disclosure is not limited thereto. In another embodiment, each of the subpixels PXn may emit light of the same color. FIG. 2 illustrates that the pixel PX may include three subpixels PXn, but the disclosure is not limited thereto. In another embodiment, the pixel PX may include more than three subpixels PXn.

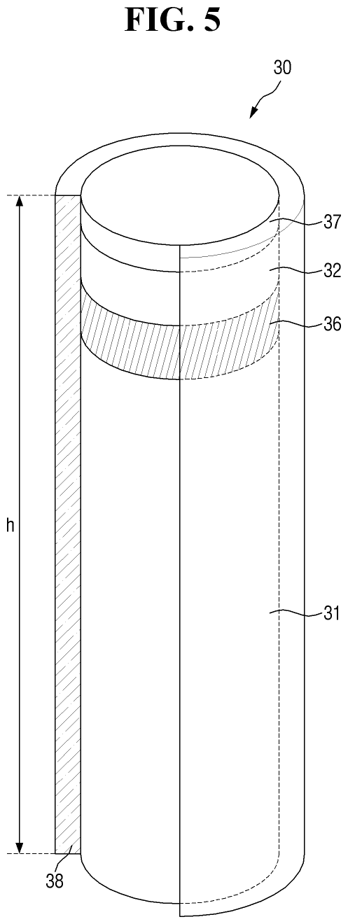

The subpixels PXn may include areas defined as emission areas EMA. The first subpixel PX1 may include a first emission area EMA1, the second subpixel PX2 may include a second emission area EMA2, and the third subpixel PX3 may include a third emission area EMA3. Each of the emission areas EMA may be defined as an area where light emitting elements 30 are disposed to emit light of a particular wavelength band. Each of the light emitting elements 30 may include an active layer (“36” of FIG. 5), and the active layer 36 may emit light of a particular wavelength band without any directivity. Light emitted by the active layers 36 of the light emitting elements 30 may be emitted through both sides of each of the light emitting elements 30. Each of the emission areas EMA may include an area where the light emitting elements 30 are disposed and may also include an area around where the light emitting elements 30 are disposed and output light.

However, the disclosure is not limited to this. Each of the emission areas EMA may include an area where light emitted by the light emitting elements 30 is reflected or refracted from other elements. The light emitting elements 30 may be disposed in each of the subpixels PXn, and the area where the light emitting elements 30 are disposed and the surrounding areas of the light emitting elements 30 may form emission areas EMA.

Although not specifically illustrated, each of the subpixels PXn of the display device 10 may include a non-emission area, which is defined as an area other than the emission areas EMA. The non-emission area may be an area where the light emitting elements 30 are not disposed and may not output light because light emitted by the light emitting elements 30 is reached.

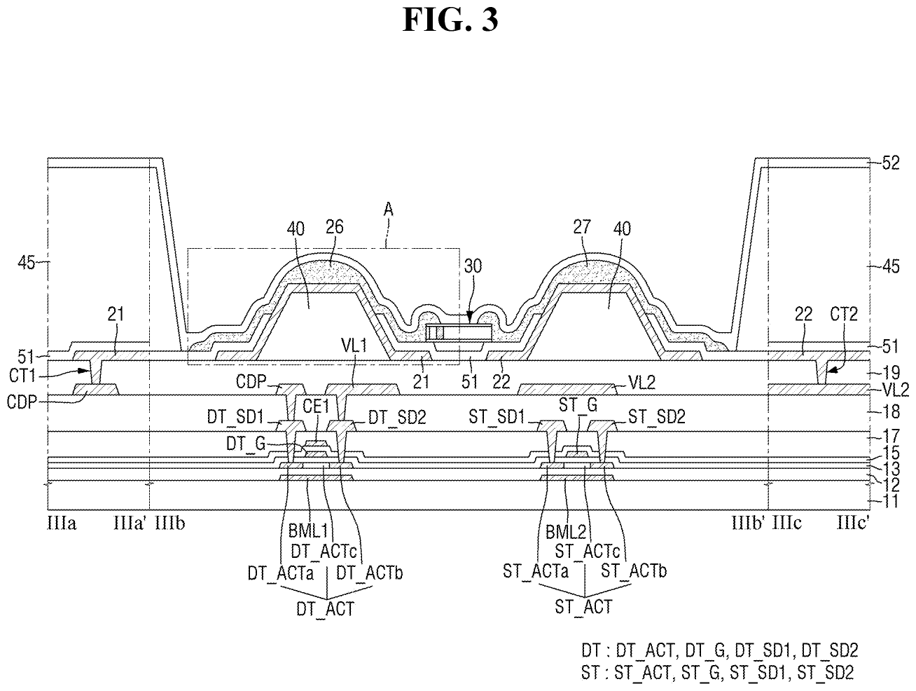

FIG. 3 is a schematic cross-sectional view taken along lines IIIa-IIIa′, IIIb-IIIb′, and IIIc-IIIc′ of FIG. 2. FIG. 3 illustrates a schematic cross-sectional view of the first subpixel PX1 of FIG. 2, which, however, may also be applicable to other pixels PX or other subpixels PXn. FIG. 3 illustrates a schematic cross-sectional view taken from an end portion to another end portion of a light emitting element 30 in the first subpixel PX1.

Referring to FIG. 3 and further to FIG. 2, the display device 10 may include a circuit element layer and a display element layer, which are disposed on a first substrate 11. A semiconductor layer, multiple conductive layer, and multiple insulating layers may be disposed on the first substrate 11 and may form the circuit element layer and the display element layer. The conductive layers may include a first gate conductive layer, a second gate conductive layer, a first data conductive layer, a second data conductive layer, electrodes (21 and 22), and contact electrodes (26 and 27). The insulating layers may include a buffer layer 12, a first gate insulating layer 13, a first passivation layer 15, a first interlayer insulating layer 17, a second interlayer insulating layer 18, a first planarization layer 19, a first insulating layer 51, and a second insulating layer 52.

For example, the first substrate 11 may be an insulating substrate. The first substrate 11 may include an insulating material such as glass, quartz, or a polymer resin. The first substrate 11 may be a rigid substrate or may be a flexible substrate that is bendable, foldable, or rollable.

Light-blocking layers (BML1 and BML2) may be disposed on the first substrate 11. The light-blocking layers (BML1 and BML2) may include first and second light-blocking layers BML1 and BML2. The first and second light-blocking layers BML1 and BML2 may be disposed to overlap at least a first active material layer DT_ACT of the driving transistor DT and a second active material layer ST_ACT of the switching transistor ST, respectively. The light-blocking layers (BML1 and BML2) may include a material capable of blocking light and may prevent light from being incident upon the first and second active material layers DT_ACT and ST_ACT. For example, the first and second light-blocking layers BML1 and BML2 may include an opaque metal material capable of blocking the transmission of light. However, the disclosure is not limited to this, and in another embodiment, the light-blocking layers BML1 and BML2 may not be provided.

The buffer layer 12 may include the light-blocking layers (BML1 and BML2) and may be disposed on the entire surface of the first substrate 11. The buffer layer 12 may be formed on the first substrate 11 to protect the driving and switching transistors DT and ST from moisture that may penetrate the first substrate 11, which is susceptible to moisture, and may perform a surface planarization function. The buffer layer 12 may include multiple inorganic layers that are alternately stacked each other. For example, the buffer layer 12 may be formed as a multilayer in which inorganic layers including at least one of silicon oxide (SiOₓ), silicon nitride (SiNₓ), and silicon oxynitride (SiON) are alternately stacked each other.

The semiconductor layer may be disposed on the buffer layer 12. The semiconductor layer may include the first active material layer DT_ACT of the driving transistor DT and the second active material layer ST_ACT of the switching transistor ST. The first active material layer DT_ACT of the driving transistor DT and the second active material layer ST_ACT of the switching transistor ST may be disposed to partially overlap gate electrodes (DT_G and ST_G) of the first gate conductive layer.

In an embodiment, the semiconductor layer may include polycrystalline silicon, monocrystalline silicon, or an oxide semiconductor. Polycrystalline silicon may be formed by crystallizing amorphous silicon. In a case where the semiconductor layer includes polycrystalline silicon, the first active material layer DT_ACT may include a first doped region DT_ACTa, a second doped region DT_ACTb, and a first channel region DT_ACTc. The first channel region DT_ACTc may be disposed between the first and second doped regions DT_ACTa and DT_ACTb. The second active material layer ST_ACT may include a third doped region ST_ACTa, a fourth doped region ST_ACTb, and a second channel region ST_ACTc. The second channel region ST_ACTc may be disposed between the third and fourth doped regions ST_ACTa and ST_ACTb. The first, second, third, and fourth doped regions DT_ACTa, DT_ACTb, ST_ACTa, and ST_ACTb may be portions of the first or second active material layer DT_ACT or ST_ACT that are doped with impurities.

In another embodiment, the first and second active material layers DT_ACT and ST_ACT may include an oxide semiconductor. The doped regions of each of the first and second active material layers DT_ACT and ST_ACT may be conductor regions. The oxide semiconductor may be an oxide semiconductor containing indium (In). In some embodiments, the oxide semiconductor may include indium-tin oxide (ITO), indium-zinc oxide (IZO), indium-gallium oxide (IGO), indium-zinc-tin oxide (IZTO), indium-gallium-tin oxide (IGTO), or indium-gallium-zinc-tin oxide (IGZTO), but the disclosure is not limited thereto.

The first gate insulating layer 13 may be disposed on the semiconductor layer and the buffer layer 12. The first gate insulating layer 13 may be disposed on the buffer layer 12, including the semiconductor layer. The first gate insulating layer 13 may function as a gate insulating film for the driving transistor DT and the switching transistor ST. The first gate insulating layer 13 may be formed as an inorganic layer including an inorganic material such as, for example, SiOₓ, SiNₓ, or SiON or as a stack of such inorganic materials.

The first gate conductive layer may be disposed on the first gate insulating layer 13. The first gate conductive layer may include a first gate electrode DT_G of the driving transistor DT and a second gate electrode ST_G of the switching transistor ST. The first gate electrode DT_G may be disposed to overlap the first channel region DT_ACTc of the first active material layer DT_ACT in a thickness direction, and the second gate electrode ST_G may be disposed to overlap the second channel region ST_ACTc of the second active material layer ST_ACT in the thickness direction.

The first gate conductive layer may be formed as a single layer or a multilayer including one of molybdenum (Mo), aluminum (Al), chromium (Cr), gold (Au), titanium (Ti), nickel (Ni), neodymium (Nd), copper (Cu), and an alloy thereof, but the disclosure is not limited thereto.

The first passivation layer 15 may be disposed on the first gate conductive layer. The first passivation layer 15 may be disposed to cover and protect the first gate conductive layer. The first passivation layer 15 may be formed as an inorganic layer including an inorganic material such as, for example, SiOₓ, SiNₓ, or SiON or as a stack of such inorganic materials.

The second gate conductive layer may be disposed on the first passivation layer 15. The second gate conductive layer may include a first capacitance electrode CE1 of a storage capacitor, which is disposed to at least partially overlap the first gate electrode DT_G in the thickness direction. The first capacitance electrode CE1 may overlap the first gate electrode DT_G in the thickness direction with the first passivation layer 15 interposed therebetween, and the storage capacitor may be formed between the first capacitance electrode CE1 and the first gate electrode DT_G. The second gate conductive layer may be formed as a single layer or a multilayer including one of Mo, Al, Cr, Au, Ti, Ni, Nd, Cu, and an alloy thereof, but the disclosure is not limited thereto.

The first interlayer insulating layer 17 may be disposed on the second gate conductive layer. The first interlayer insulating layer 17 may function as an insulating film between the second gate conductive layer and layers disposed on the second gate conductive layer. The first interlayer insulating layer 17 may be formed as an inorganic layer including an inorganic material such as, for example, SiOₓ, SiNₓ, or SiON or as a stack of such inorganic materials.

The first data conductive layer may be disposed on the first interlayer insulating layer 17. The first data conductive layer may include a first source/drain electrode DT_SD1 and a second source/drain electrode DT_SD2 of the driving transistor DT and a first source/drain electrode ST_SD1 and a second source/drain electrode ST_SD2 of the switching transistor ST.

The first source/drain electrode DT_SD1 and the second source/drain electrode DT_SD2 of the driving transistor DT may be in contact with the first and second doped regions DT_ACTa and DT_ACTb of the first active material layer DT_ACT through contact holes penetrating the first interlayer insulating layer 17 and the first gate insulating layer 13. The first source/drain electrode ST_SD1 and the second source/drain electrode ST_SD2 of the switching transistor ST may be in contact with the third and fourth doped regions ST_ACTa and ST_ACTb of the second active material layer ST_ACT through contact holes penetrating the first interlayer insulating layer 17 and the first gate insulating layer 13. The first source/drain electrode DT_SD1 of the driving transistor DT and the first source/drain electrode ST_SD1 of the switching transistor ST may be electrically connected to the first and second light-blocking layers BML1 and BML2, respectively, through other contact holes. If one of the first and second source/drain electrodes DT_SD1 and DT_SD2 of the driving transistor DT or one of the first and second source/drain electrodes ST_SD1 and ST_SD2 of the switching transistor ST is a source electrode, the other of the source/drain electrodes may be a drain electrode, but the disclosure is not limited thereto. In another embodiment, if one of the first and second source/drain electrodes DT_SD1 and DT_SD2 of the driving transistor DT or one of the first and second source/drain electrodes ST_SD1 and ST_SD2 of the switching transistor ST is a drain electrode, the other of the source/drain electrode may be a source electrode.

The first data conductive layer may be formed as a single layer or a multilayer including one of Mo, Al, Cr, Au, Ti, Ni, Nd, Cu, and an alloy thereof, but the disclosure is not limited thereto.

The second interlayer insulating layer 18 may be disposed on the first data conductive layer. The second interlayer insulating layer 18 may be disposed on the entire surface of the first interlayer insulating layer 17, covering the first data conductive layer, and may protect the first data conductive layer. The second interlayer insulating layer 18 may be formed as an inorganic layer including an inorganic material such as, for example, SiOₓ, SiNₓ, or SiON or as a stack of such inorganic materials.

The second data conductive layer may be disposed on the second interlayer insulating layer 18. The second data conductive layer may include a first voltage line VL1, a second voltage line VL2, and the first conductive pattern CDP. A high-potential voltage (or a first power supply voltage VDD), which is supplied to the driving transistor DT, may be applied to the first voltage line VL1, and a low-potential voltage (or a second power supply voltage VSS), which is supplied to a second electrode 22, may be applied to the second voltage line VL2. An alignment signal for aligning the light emitting elements 30 may be applied to the second voltage line VL2 during the fabrication of the display device 10.

The first conductive pattern CDP may be electrically connected to the first source/drain electrode DT_SD1 of the driving transistor DT through a contact hole formed in the second interlayer insulating layer 18. The first conductive pattern CDP may be in contact with a first electrode 21 that will be described later, and the driving transistor DT may transmit the second power supply voltage VDD from the first voltage line VL1 to the first electrode 21 through the first conductive pattern CDP. The second data conductive layer is illustrated as including one second voltage line VL2 and one first voltage line VL1 in FIG. 3, but the disclosure is not limited thereto. In another embodiment, the second data conductive layer may include more than one first voltage line VL1 and more than one second voltage line VL2.

The second data conductive layer may be formed as a single layer or a multilayer including one of Mo, Al, Cr, Au, Ti, Ni, Nd, Cu, and an alloy thereof, but the disclosure is not limited thereto.

The first planarization layer 19 may be disposed on the second data conductive layer. The first planarization layer 19 may include an organic insulating material, particularly, an organic material such as, for example, polyimide (PI), and may perform a surface planarization function.

Multiple first banks 40, multiple electrodes (21 and 22), light emitting elements 30, a second bank 45, and multiple contact electrodes (26 and 27) may be disposed on the first planarization layer 19. Multiple insulating layers (51 and 52) may be also disposed on the first planarization layer 19.

The first banks 40 may be disposed directly on the first planarization layer 19. The first banks 40 may extend in the second direction DR2, in each of the subpixels PXn, and may be spaced apart from, and terminated at, the boundaries between neighboring subpixels PXn in the second direction DR2, not to extend into other subpixels PXn. Also, the first banks 40 may be disposed to be spaced apart from, and face each other in the first direction DR1. The first banks 40 may be spaced apart from each other in each of the subpixels PXn to form an area in which the light emitting elements 30 are arranged therebetween. The first banks 40 may be disposed in each of the subpixels PXn to form linear patterns in the display area DPA of the display device 10. FIG. 3 illustrates two first banks 40 are disposed in each of the subpixels PXn, but the disclosure is not limited thereto. More than two first banks 40 may be provided depending on the number of electrodes (21 and 22) that will be described later.

The first banks 40 may protrude at least in part from the top surface of the first planarization layer 19. In an embodiment, the middle portions of the first banks 40 may be thicker than the rest of the first banks 40. The middle portions of protruding portions of the first banks 40 may be thicker, and each of the protruding portions of the first banks 40 may have inclined sides. Light emitted by the light emitting elements 30 may travel toward the inclined sides of each of the first banks 40. The electrodes (21 and 22), which are disposed on the first banks 40, may include a material with high reflectance, and light emitted by the light emitting elements 30 may be reflected by the electrodes (21 and 22) from sides of the first banks 40 to be emitted in an upward direction of the first planarization layer 19. For example, the first banks 40 may provide a space in which the light emitting elements 30 are arranged, and also function as reflective partition walls capable of reflecting light emitted by the light emitting elements 30 to the upward direction. The sides of each of the first banks 40 may be linearly inclined, but the disclosure is not limited thereto. In another embodiment, the sides of each of the first banks 40 may have a curved semicircular or semielliptical shape. In an embodiment, the first banks 40 may include an organic insulating material such as PI, but the disclosure is not limited thereto.

The electrodes (21 and 22) may be disposed on the first banks 40 and the first planarization layer 19. The electrodes (21 and 22) may include first and second electrodes 21 and 22. The first and second electrodes 21 and 22 may extend in the second direction DR2 and may be disposed to be spaced apart from, and face each other in the first direction DR1. The first and second electrodes 21 and 22 may have a substantially similar shape to the first banks 40 and may be longer than the first banks 40 in the second direction DR2.

The first electrode 21 may extend in the second direction DR2 in each of the subpixels PXn, and may be spaced apart from another first electrode 21 at the boundary between two adjacent subpixels PXn in the second direction DR2. In some embodiments, the second bank 45 may be disposed along the boundaries of each of the subpixels PXn, and first electrodes 21 of adjacent subpixels PXn in the second direction DR2 may be spaced apart from each other with the second bank 45 interposed therebetween. The first electrode 21 may be electrically connected to the driving transistor DT. For example, at least part of the first electrode 21 may be disposed to overlap a part of the second bank 45 that extends in the first direction DR1 and may be in contact with the first conductive pattern CDP through a first contact hole CT1, which penetrates the first planarization layer 19. The first electrode 21 may be electrically connected to the first source/drain electrode DT_SD1 of the driving transistor DT through the first conductive pattern CDP.

The second electrode 22 may extend in the second direction DR2 beyond the boundaries between adjacent subpixels PXn in the second direction DR2. In some embodiments, a second electrode 22 may be disposed in multiple adjacent subpixels PXn in the second direction DR2. The second electrode 22 may partially overlap the second bank 45 at the boundary between the adjacent subpixels SPXn in the second direction DR2, and may be electrically connected to the second voltage line VL2 through a second contact hole CT2. For example, the second electrode 22 may be disposed to overlap a portion of the second bank 45 that extend in the first direction DR1, and may be in contact with the second voltage line VL2 through the second contact hole CT2, which penetrates the first planarization layer 19. The second electrode 22 is illustrated as being electrically connected to the second voltage line VL2 through a second contact hole CT2 disposed at a boundary of each of the subpixels SPXn, but the disclosure is not limited thereto. In some embodiments, a second contact hole CT2 may be disposed in each of the subpixels PXn.

Each of the subpixels PXn is illustrated as including one first electrode 21 and one second electrode 22, but the disclosure is not limited thereto. In another embodiment, more than one first electrode 21 and more than one second electrode 22 may be disposed in each of the subpixels PXn. The first and second electrodes 21 and 22, which are disposed in each of the subpixels PXn, may not necessarily extend in one direction, but may be arranged in various layouts. For example, the first and second electrodes 21 and 22 may be partially curved or bent, and one of the first and second electrodes 21 and 22 may be disposed to surround the other electrode. At least portions of the first and second electrodes 21 and 22 may be spaced apart from, and face each other, and the structures and shapes of the first and second electrodes 21 and 22 are not particularly limited if an area in which the light emitting elements 30 are arranged is formed.

The electrodes (21 and 22) may be electrically connected to the light emitting elements 30, and predetermined (or selectable) voltages may be applied to the electrodes (21 and 22) such that the light emitting elements 30 may emit light. For example, the electrodes (21 and 22) may be electrically connected to the light emitting elements 30, and electrical signals applied to the electrodes (21 and 22) may be transmitted to the light emitting elements 30 through the contact electrodes (26 and 27).

In an embodiment, the first electrode 21 may be separated between multiple subpixels PXn, and the second electrode 22 may be electrically connected in common throughout the multiple subpixels PXn. One of the first and second electrodes 21 and 22 may be electrically connected to the anodes of the light emitting elements 30, and the other electrode may be electrically connected to the cathodes of the light emitting elements 30. However, the disclosure is not limited to this. In another embodiment, one of the first and second electrodes 21 and 22 may be electrically connected to the cathodes of the light emitting elements 30, and the other electrode may be electrically connected to the anodes of the light emitting elements 30. In another embodiment, both the first and second electrodes 21 and 22 may be separated between the multiple subpixels PXn.

The electrodes (21 and 22) may be used to generate an electric field in each of the subpixels PXn to align the light emitting elements 30. The light emitting elements 30 may be disposed between the first and second electrodes 21 and 22 by an electric field formed on the first and second electrodes 21 and 22. As will be described later, the light emitting elements 30 may be sprayed onto the first and second electrodes 21 and 22 in a state of being dispersed in ink through inkjet printing, and in response to an alignment signal applied between the first and second electrodes 21 and 22, the light emitting elements 30 may be aligned between the first and second electrodes 21 and 22 by applying a dielectrophoretic force.

As illustrated in FIG. 3, the first and second electrodes 21 and 22 may be disposed on the first banks 40. The first and second electrodes 21 and 22 may be spaced apart from, and face each other in the first direction DR1, and light emitting elements 30 may be disposed between the first and second electrodes 21 and 22. The light emitting elements 30 may be disposed between the first and second electrodes 21 and 22, and at the same time, electrically connected to the first and second electrodes 21 and 22.

In some embodiments, the first and second electrodes 21 and 22 may be formed to have a larger width than the first banks 40. For example, the first and second electrodes 21 and 22 may be disposed to cover the outer surfaces of the first banks 40. The first and second electrodes 21 and 22 may be disposed on sides of the first banks 40, and the distance between the first and second electrodes 21 and 22 may be less than the distance between the first banks 40. Also, at least portions of the first and second electrodes 21 and 22 may be disposed directly on the first planarization layer 19.

The electrodes (21 and 22) may include a transparent conductive material. For example, the electrodes (21 and 22) may include a material such as ITO, IZO, or ITZO, but the disclosure is not limited thereto. In some embodiments, the electrodes (21 and 22) may include a conductive material with high reflectance. For example, the electrodes (21 and 22) may include a material with high reflectance such as silver (Ag), copper (Cu), or Al. In the embodiment, the electrodes (21 and 22) may reflect light emitted by the light emitting elements 30 that travels toward sides of the first banks 40 to an upward direction of each of the subpixels PXn.

However, the disclosure is not limited to this. In another embodiment, the electrodes (21 and 22) may have a stack of one or more layers of a transparent conductive material and one or more layers of a metal with high reflectance or may be formed as a single layer including the transparent conductive material and the metal with high reflectance. In an embodiment, the electrodes (21 and 22) may have a stack of ITO/Ag/ITO, ITO/Ag/IZO, or ITO/Ag/ITZO/IZO or may include an alloy of Al, Ni, or lanthanum (La).

The first insulating layer 51 may be disposed on the first planarization layer 19, the first electrode 21, and the second electrode 22. The first insulating layer 51 may be disposed to cover the first and second electrodes 21 and 22 and the gap between the first and second electrodes 21 and 22. For example, the first insulating layer 51 may cover most of upper surfaces of the first and second electrodes 21 and 22, but may expose portions of the first and second electrodes 21 and 22. The first insulating layer 51 may be disposed to expose portions of the top surfaces of the first and second electrodes 22 on, for example, the first banks 40. The first insulating layer 51 may be formed on substantially the entire surface of the first planarization layer 19 and may include openings (not illustrated), which partially expose the first and second electrodes 21 and 22.

In an embodiment, the first insulating layer 51 may be stepped such that part of the upper surface of the first insulating layer 51 is recessed between the first and second electrodes 21 and 22. In some embodiments, the first insulating layer 51 may include an inorganic insulating material, and part of the upper surface of the first insulating layer 51, which is disposed to cover the first and second electrodes 21 and 22, may be recessed due to the height differences formed by the underlying elements. The light emitting elements 30, which are disposed on the first insulating layer 51, between the first and second electrodes 21 and 22, may form empty spaces with the recessed part of the upper surface of the first insulating layer 51. The light emitting elements 30 may be disposed to be spaced apart from the upper surface of the first insulating layer 51, and the space between the first insulating layer 51 and the light emitting elements 30 may be filled with the material of the contact electrodes (26 and 27) that will be described later. However, the disclosure is not limited to this. The first insulating layer 51 may form a flat surface on which the light emitting elements 30 is arranged.

The first insulating layer 51 may protect the first and second electrodes 21 and 22 and may insulate the first and second electrodes 21 and 22 from each other. Also, the first insulating layer 51 may prevent the light emitting elements 30, which are disposed on the first insulating layer 51, from being in direct contact with, and damaged by, other elements. However, the shape and structure of the first insulating layer 51 are not particularly limited.

The second bank 45 may be disposed on the first insulating layer 51. In some embodiments, the second bank 45 may surround the regions where the first banks 40 are disposed and the regions where the light emitting elements 30 are disposed, on the first insulating layer 51 and may be arranged along the boundaries between the subpixels PXn. The second bank 45 may be disposed to extend in the first and second directions DR1 and DR2 and may thus form a lattice pattern on the entire surface of the display area DPA. Portions of the second bank 45 that extend in the first direction DR1 may partially overlap the first and second electrodes 21 and 22, and portions of the second bank 45 that extend in the second direction DR2 may be spaced apart from the first banks 40 and the first and second electrodes 21 and 22.

The height of the second bank 45 may be greater than the height of the first banks 40. The second bank 45, unlike the first banks 40, may separate neighboring subpixels PXn and may prevent ink from spilling over between the neighboring subpixels PXn during inkjet printing for aligning the light emitting elements 30 during the fabrication of the display device 10. The second bank 45 may separate ink having different sets of light emitting elements 30 not to be mixed each other. The second bank 45, like the first banks 40, may include PI, but the disclosure is not limited thereto.

The light emitting elements 30 may be disposed between the electrodes (21 and 22). In an embodiment, the light emitting elements 30 may extend in a direction and may be disposed to be spaced apart from one another and aligned substantially in parallel with one another. The distance between the light emitting elements 30 is not particularly limited. Some of the light emitting elements 30 may be disposed adjacent to one another to form a group, and some other light emitting elements 30 may be disposed with a predetermined (or selectable) distance from the group to form another group. In another embodiment, the light emitting elements 30 may be arranged with a nonuniform density. Also, the direction in which the electrodes (21 and 22) extend may form a substantially right angle with the direction in which the light emitting elements 30 extend. However, the disclosure is not limited to this. In another embodiment, the light emitting elements 30 may extend diagonally with respect to the direction in which the electrodes (21 and 22) extend.

Each of the light emitting elements 30 may include an active layer (“36” of FIG. 5) including different materials and may thus emit light of different wavelength bands to the outside. The display device 10 may include light emitting elements 30 capable of emitting light of different wavelength bands. For example, the light emitting elements 30 of the first subpixel PX1 may include active layers 36 emitting first-color light having a first wavelength as a central wavelength, the light emitting elements 30 of the second subpixel PX2 may include active layers 36 emitting second-color light having a second wavelength as a central wavelength, and the light emitting elements 30 of the third subpixel PX3 may include active layers 36 emitting third-color light having a third wavelength as a central wavelength.

Accordingly, the first, second, and third subpixels PX1, PX2, and PX3 may emit the first-color light, the second-color light, and the third-color light, respectively. In some embodiments, the first-color light may be blue light having a central wavelength of about 450 nm to about 495 nm, the second-color light may be green light having a central wavelength of about 495 nm to about 570 nm, and the third-color light may be red light having a central wavelength of about 620 nm to about 752 nm. However, the disclosure is not limited to this. In another embodiment, the first, second, and third subpixels PX1, PX2, and PX3 may include light emitting elements 30 of the same type and may thus all emit light of the same color.

The light emitting elements 30 may be disposed on the first insulating layer 51, between the first banks 40 or between the electrodes (21 and 22). For example, at least one end portion of each of the light emitting elements 30 may be disposed on the first or second electrode 21 or 22. The length of the light emitting elements 30 may be greater than the distance between the first and second electrodes 21 and 22, and both end portions of each of the light emitting elements 30 may be disposed on the first and second electrodes 21 and 22. However, the disclosure is not limited to this. In another embodiment, only one end portion of each of the light emitting elements 30 may be disposed on the electrodes (21 and 22), or neither of end portions of each of the light emitting elements 30 may be disposed on any electrodes (21 and 22). Even if the light emitting elements 30 are not disposed on the electrodes (21 and 22), both end portions of each of the light emitting elements 30 may be electrically connected to the electrodes (21 and 22) through the contact electrodes (26 and 27) that will be described later. In some embodiments, at least portions of the light emitting elements 30 may be disposed between the first and second electrodes 21 and 22, and both end portions of each of the light emitting elements 30 may be electrically connected to the electrodes (21 and 22).

Also, although not specifically illustrated, at least some of the light emitting elements 30, which are disposed in each of the subpixels PXn, may be disposed in areas other than that formed between the first banks 40, for example, on the electrodes (21 and 22) or between the first banks 40 and the second bank 45.

In each of the light emitting elements 30, multiple layers may be arranged in a direction perpendicular to the top surface of the first substrate 11 or the first planarization layer 19. The light emitting elements 30 may extend in a direction and may have a structure in which multiple semiconductor layers are sequentially arranged. The light emitting elements 30 may be disposed such that the direction in which the light emitting elements 30 of the display device 10 extend may be parallel to the first planarization layer 19, and the semiconductor layers included in each of the light emitting elements 30 may be sequentially arranged in a direction parallel to the top surface of the first planarization layer 19. However, the disclosure is not limited to this. In a case where the light emitting elements 30 have a different structure, the layers of each of the light emitting elements 30 may be arranged in a direction perpendicular to the first planarization layer 19.

Also, both end portions of each of the light emitting elements 30 may be in contact with the contact electrodes (26 and 27). As an insulating film (“38” of FIG. 5) is not formed, and some of the semiconductor layers of each of the light emitting elements 30 are exposed on both end surfaces in the extension direction of each of the light emitting elements 30, the exposed semiconductor layers may be in contact with the contact electrodes (26 and 27), but the disclosure is not limited thereto. At least part of the insulating film 38 of each of the light emitting elements 30 may be removed, and sides of the semiconductor layers of each of the light emitting elements 30 may be partially exposed. The exposed sides of the semiconductor layers of each of the light emitting elements 30 may be in direct contact with the contact electrodes (26 and 27).

The contact electrodes (26 and 27) may be disposed on the electrodes (21 and 22) and the light emitting elements 30. The contact electrodes (26 and 27) may include a first contact electrode 26, which is disposed on the first electrode 21 and is in contact with first end portions of the light emitting elements 30, and a second contact electrode 27, which is disposed on the second electrode 22 and is in contact with second end portions of the light emitting elements 30.

The first and second contact electrodes 26 and 27 may have a similar shape to the first banks 40. For example, the first and second contact electrodes 26 and 27 may extend in the second direction DR2, in each of the subpixels PXn, and may be disposed to be spaced apart from, and face each other in the first direction DR1. The first and second contact electrodes 26 and 27 may be spaced apart from, and face each other in the region where the light emitting elements 30 are disposed, for example, between the first and second electrodes 21 and 22. The contact electrodes (26 and 27) may be disposed in each area surrounded by the second bank 45 to be spaced apart from the boundaries between neighboring subpixels PXn. In some embodiments, the contact electrodes (26 and 27) may form linear patterns in each of the subpixels PXn.

The first and second contact electrodes 26 and 27 may be in contact with portions of the top surfaces of the first and second electrodes 21 and 22 that are exposed due to the absence of the first insulating layer 51 thereon. Also, the contact electrodes (26 and 27) may be in contact with both end portions of each of the light emitting elements 30. In some embodiments, the contact electrodes (26 and 27) may include a conductive material, and the light emitting elements 30 may be electrically connected to the electrodes (21 and 22) through the contact electrodes (26 and 27). As described above, semiconductor layers may be partially exposed at both ends of each of the light emitting elements 30, and the contact electrodes (26 and 27) may be in direct contact with the exposed semiconductor layers. The first and second contact electrodes 26 and 27 may extend in the second direction DR2 and may be disposed to surround portions of the outer surfaces of the light emitting elements 30, which are disposed between the electrodes (21 and 22).

In some embodiments, the width of the first and second contact electrodes 26 and 27 may be the same as or greater than the width of the first and second electrodes 21 and 22. The first and second contact electrodes 26 and 27 may be in contact with the first and second end portions, respectively, of each of the light emitting elements 30 and may be disposed to cover both sides of each of the first and second electrodes 21 and 22. As described above, portions of the top surfaces of the first and second electrodes 21 and 22 may be exposed, and the first and second contact electrodes 26 and 27 may be in contact with the exposed portions of the first and second electrodes 21 and 22. For example, the contact electrodes (26 and 27) may be in contact with portions of the first and second electrodes 21 and 22 on the first banks 40. Also, as illustrated in FIG. 3, at least portions of the first and second contact electrodes 26 and 27 may be disposed on the first insulating layer 51. However, the disclosure is not limited to this. The width of the first and second contact electrodes 26 and 27 may be less than the width of the first and second electrodes 21 and 22 such that the first and second contact electrodes 26 and 27 may cover only the exposed portions of the top surfaces of the first and second electrodes 21 and 22.

One first contact electrode 26 and one second contact electrode 27 are illustrated as being disposed in one subpixel PXn, but the disclosure is not limited thereto. The numbers of first contact electrodes 26 and second contact electrodes 27 may vary depending on the numbers of first electrodes 21 and second electrodes 22 in each of the subpixels PXn.

During the fabrication of the display device 10, a process of fixing the locations of the light emitting elements 30 after arranging the light emitting elements 30 on the electrodes (21 and 22) may be needed. For example, in a case where the contact electrodes (26 and 27) are formed directly on the light emitting elements 30 and the electrodes (21 and 22), the locations of the light emitting elements 30 may change during the deposition of the material of the contact electrodes (26 and 27). However, as the locations of the light emitting elements 30 are fixed before the formation of the contact electrodes (26 and 27), the electrodes (21 and 22) and the light emitting elements 30 may be properly connected electrically. The contact electrodes (26 and 27) of the display device 10 may include a material having conductivity and capable of fixing the locations of the light emitting elements 30 during the fabrication of the display device 10.

The contact electrodes (26 and 27) may include a transparent conductive polymer. In a case where the contact electrodes (26 and 27) include a polymer, the contact electrodes (26 and 27) may perform the function of fixing the alignment locations of the light emitting elements 30 during the fabrication of the display device 10. Also, as the material of the contact electrodes (26 and 27) has conductivity, the contact electrodes (26 and 27) may electrically connect the light emitting elements 30 and the electrodes (21 and 22). Also, as the contact electrodes (26 and 27) include a transparent material, light emitted by the light emitting elements 30 may be output through the contact electrodes (26 and 27).

Examples of the conductive polymer may include, but are not limited to, polyethylene dioxythiophene (PEDOT), polyethylene dioxythiophene polystyrene sulfonate (PEDOT:PSS), poly(3-alkyl)thiophene (P3AT), poly(3-hexyl)thiophene (P3HT), polyaniline, polyacetylene, polyazulene, polyisothianapthalene, polyisothianaphthene, polythienylenevinylene, polythiophene, polyphenylene, polyphenylene sulfide, polyparaphenylene, polyparaphenylene vinylene, polyfuran, polypyrrole, and polyheptadiyne. In some embodiments, the conductive polymer included in the contact electrodes (26 and 27) may be PEDOT:PSS. PEDOT:PSS may include a polymer chain formed of PEDOT and electric charges formed in the side chain portion of PSS and thus may have electric conductivity. Also, as PEDOT:PSS has transparency, the contact electrodes (26 and 27) including PEDOT:PSS may constitute transparent conductive electrodes of, for example, ITO. Light emitted from both end portions of each of the light emitting elements 30 may be reflected by the electrodes (21 and 22) through the contact electrodes (26 and 27) and may thus be emitted in an upward direction of the first substrate 11.

The contact electrodes (26 and 27) may have a predetermined (or selectable) thickness. In case that the contact electrodes (26 and 27) are thin, the light transmittance of the contact electrodes (26 and 27) may be high, but the resistance of the contact electrodes (26 and 27) may also be high. On the contrary, in case that the thickness of the contact electrodes (26 and 27) is increased in consideration of resistance, the light transmittance of the contact electrodes (26 and 27) may be low. In an embodiment, the contact electrodes (26 and 27) may have a thickness of about 150 nm to about 250 nm or about 200 nm. In this embodiment, the contact electrodes (26 and 27) may have low resistance and high light transmittance.

The contact electrodes (26 and 27) may be formed by spraying ink including the conductive polymer into each of the subpixels PXn and curing the conductive polymer. The conductive polymer may be dispersed in the ink together with the light emitting elements 30, and in case that the light emitting elements 30 are aligned between the electrodes (21 and 22), the conductive polymer may agglomerate (or aggregate) on the electrodes (21 and 22) and both end portions of each of the light emitting elements 30. The conductive polymer may fix the light emitting elements 30 while being in contact with the light emitting elements 30 and the electrodes (21 and 22) and may be cured later to form the contact electrodes (26 and 27). As the conductive polymer is dispersed in ink and agglomerates to form the contact electrodes (26 and 27), the contact electrodes (26 and 27) may not have a uniform thickness.

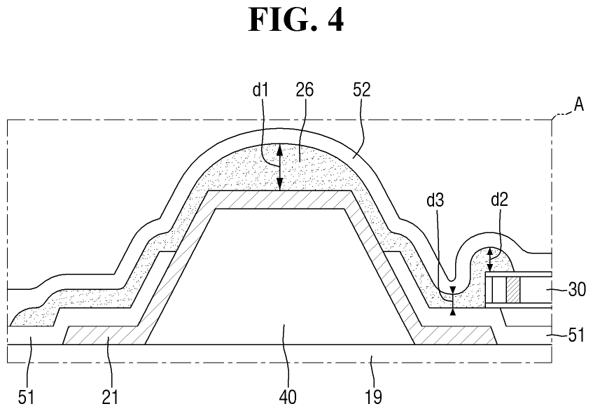

FIG. 4 is an enlarged schematic cross-sectional view of part A of FIG. 3. FIG. 4 illustrates part of the display device 10 where the first electrode 21 and the first contact electrode 26 are disposed, on one of the first banks 40.

Referring to FIG. 4, the thickness of the contact electrodes (26 and 27) may not be uniform, and a portion of the contact electrodes (26 and 27) may be thicker than the rest of the contact electrodes (26 and 27). The middle portions of the first banks 40 may be thicker than the rest of the first banks 40, and the contact electrodes (26 and 27) may be disposed to overlap at least portions of the first banks 40 in the thickness direction. FIG. 4 illustrates that the first contact electrode 26 completely overlaps one of the first banks 40, but the disclosure is not limited thereto.

The first contact electrode 26 may include a first portion, which is disposed to overlap a thick part of a first bank 40, a second portion, which covers the first end portions of the light emitting elements 30, and a third portion, which accounts for at least part of the first contact electrode 26 and is disposed directly on the first insulating layer 51 on the first electrode 21. During the fabrication of the display device 10, the conductive polymer of the contact electrodes (26 and 27) may agglomerate on the electrodes (21 and 22) and the first insulating layer 51 along the outer surface of the first bank 40, which protrudes. The conductive polymer may be dispersed in ink, and as the main chain part of the conductive polymer is aligned in one direction by an electric field formed on the electrodes (21 and 22), the conductive polymer may agglomerate on the electrodes (21 and 22) and the light emitting elements 30. Here, the conductive polymer may agglomerate mainly at particular locations due to the height differences formed by the electrodes (21 and 22) and the light emitting elements 30.

A thickness d1 of portions of the contact electrodes (26 and 27) that are disposed to overlap thick portions of the first banks 40 may be greater than the thickness of the rest of the contact electrodes (26 and 27). The electrodes (21 and 22) where the contact electrodes (26 and 27) are disposed may have a greatest height from the first planarization layer 19, on the thick portions of the first banks 40. The conductive polymer may agglomerate mainly in regions where the electrodes (21 and 22) have a greatest height, and the thickness d1 of the first portions of the contact electrodes (26 and 27) may be greater than the thickness of the rest of the contact electrodes (26 and 27).

Also, the contact electrodes (26 and 27) may be in contact with both end portions of each of the light emitting elements 30, and a thickness d2 of the second portions of the contact electrodes (26 and 27) may be greater than a thickness of the third portions of the contact electrodes (26 and 27). Both end portions of each of the light emitting elements 30 may be disposed on the electrodes (21 and 22), and the light emitting elements 30 may be disposed at a position higher than the electrodes (21 and 22) disposed directly on the first planarization layer 19. The conductive polymer may agglomerate to cover both end portions of each of the light emitting elements 30 and may fix the locations of the light emitting elements 30 between the electrodes (21 and 22) during the fabrication of the display device 10. The thickness d2 of the second portions of the contact electrodes (26 and 27), which are lower than the first portions of the contact electrodes (26 and 27), may be greater than the thickness d3 of the third portions of the contact electrodes (26 and 27). The contact electrodes (26 and 27) may have a nonuniform thickness and may have a different shape in part from the height differences formed by the electrodes (21 and 22) and the first banks 40.

In some embodiments, the thickness d2 of the second portions of the contact electrodes (26 and 27) may be greater than the diameter of the light emitting elements 30. The second portions of the contact electrodes (26 and 27) may be thick enough to cover the light emitting elements 30 in a cross-sectional view. Accordingly, in some embodiments, the light emitting elements 30 may be disposed to have different heights in a cross-sectional view and to overlap the electrodes (21 and 22) in the thickness direction, between the electrodes (21 and 22). This will be described later.

In short, the display device 10 may include contact electrodes (26 and 27) including conductive polymer, and the contact electrodes (26 and 27) may have a nonuniform thickness. During the fabrication of the display device 10, the conductive polymer, which is included in ink in a state of being dispersed in the ink together with the light emitting elements 30, may be formed to have different thicknesses depending on the height of the electrodes (21 and 22) where the conductive polymer agglomerates. As the conductive polymer agglomerates on the electrodes (21 and 22) during the arrangement of the light emitting elements 30 between the electrodes (21 and 22), the conductive polymer may fix the locations of the light emitting elements 30, and the display device 10 may not need a separate member for fixing the light emitting elements 30. Also, during the fabrication of the display device 10, the alignment of the light emitting elements 30 between the electrodes (21 and 22) and the formation of the contact electrodes (26 and 27) may be performed substantially at the same time, and thus, the number of fabrication processes can be reduced.

As described above, part of the upper surface of the first insulating layer 51 may be stepped, and spaces may be formed between the upper surface of the first insulating layer 51 and the light emitting elements 30. In some embodiments, the conductive polymer of the contact electrodes (26 and 27) may be disposed between the bottom surfaces of the light emitting elements 30 and the first insulating layer 51. As already mentioned above, during the formation of the contact electrodes (26 and 27), the light emitting elements 30 and the conductive polymer may be dispersed together in ink, and some of the conductive polymer may be disposed to fill the spaces between the first insulating layer 51 and the light emitting elements 30. As a result, portions of the bottom surfaces of the light emitting elements 30 may be in direct contact with the conductive polymer of the contact electrodes (26 and 27). However, the disclosure is not limited to this.

Referring again to FIG. 3, the second insulating layer 52 may be disposed on the entire surface of the first substrate 11. The second insulating layer 52 may protect the elements disposed on the first substrate 11 from an external environment. In some embodiments, the second insulating layer 52 may be in direct contact with the contact electrodes (26 and 27), the first insulating layer 51, and the second bank 45, and also with the light emitting elements 30, which overlap the gap between the contact electrodes (26 and 27).

The first and second insulating layers 51 and 52 may include an inorganic insulating material or an organic insulating material. In an embodiment, the first and second insulating layers 51 and 52 may include an inorganic insulating material such as SiOₓ, SiNₓ, SiOₓNy, aluminum oxide (Al₂O₃), or aluminum nitride (AlN). In another embodiment, the first and second insulating layers 51 and 52 may include an organic insulating material such as an acrylic resin, an epoxy resin, a phenolic resin, a polyamide resin, a PI resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, or a polymethyl methacrylate-polycarbonate synthetic resin. However, the disclosure is not limited to these embodiments.

The light emitting elements 30 may be LEDs, particularly, inorganic LEDs having a size of several micro- or nano-meters and including an inorganic material. The inorganic LEDs may be aligned between two opposing electrodes where polarity is formed in response to an electric field being generated in a particular direction therebetween.

FIG. 5 is a schematic view of a light emitting element according to an embodiment of the disclosure.

Referring to FIG. 5, a light emitting element 30 may extend in a direction. The light emitting element 30 may have a rod, wire, or tube shape. In an embodiment, the light emitting element 30 may have a cylindrical or rod shape. However, the shape of the light emitting element 30 is not particularly limited, and the light emitting element 30 may have various shapes such as a polygonal prism shape, for example, a cube shape, a rectangular parallelepiped shape, or a hexagonal prism shape, or a shape extending in one direction with portions of the outer surfaces thereof inclined.

The light emitting element 30 may include semiconductor layers doped with impurities of a conductivity type (e.g., a p type or an n type). The semiconductor layers may receive electrical signals applied from an external source and may thereby emit light of a particular wavelength band. The semiconductor layers included in the light emitting element 30 may be sequentially arranged or stacked in a direction.

The light emitting element 30 may include a first semiconductor layer 31, a second semiconductor layer 32, an active layer 36, an electrode layer 37, and an insulating film 38. To properly visualize the elements of the light emitting element 30, FIG. 5 illustrates a light emitting element 30 with part of the insulating film 38 removed to expose multiple semiconductor layers (31, 32, and 36). However, as will be described later, the insulating film 38 may be disposed to surround the outer surfaces of the semiconductor layers (31, 32, and 36).

For example, the first semiconductor layer 31 may be an n-type semiconductor. For example, in a case where the light emitting element 30 emits blue-wavelength light, the first semiconductor layer 31 may include a semiconductor material, i.e., AlₓGa_{y}In_{1-x-y}N (where 0≤x≤1, 0≤y≤1, and 0≤x+y≤1). For example, the first semiconductor layer 31 may include at least one of AlGaInN, GaN, AlGaN, InGaN, AlN, and InN that are doped with an n-type dopant. The first semiconductor layer 31 may be doped with an n-type dopant, and the n-type dopant may include, for example, Si, Ge, or Sn. For example, the first semiconductor layer 31 may be GaN doped with n-type Si. The first semiconductor layer 31 may have a length of about 1.5 μm to about 5 μm, but the disclosure is not limited thereto.

The second semiconductor layer 32 may be disposed on the active layer 36 that will be described later. The second semiconductor layer 32 may be a p-type semiconductor. In a case where the light emitting element 30 emits blue- or green-wavelength light, the second semiconductor layer 32 may include a semiconductor material, i.e., AlₓGa_{y}In_{1-x-y}N (where 0≤x≤1, 0≤y≤1, and 0≤x+y≤1). For example, the second semiconductor layer 30 may include at least one of AlGaInN, GaN, AlGaN, InGaN, AlN, and InN that are doped with a p-type dopant. The second semiconductor layer 32 may be doped with a p-type dopant, and the p-type dopant may include, for example, Mg, Zn, Ca, Se, or Ba. In an embodiment, the second semiconductor layer 32 may be GaN doped with p-type Mg. The second semiconductor layer 32 may have a length of about 0.05 μm to about 0.10 μm, but the disclosure is not limited thereto.

The first and second semiconductor layers 31 and 32 are illustrated as being formed as single layers, but the disclosure is not limited thereto. In another embodiment, each of the first and second semiconductor layers 31 and 32 may include more than one layer such as, for example, a clad layer or a tensile strain barrier reducing (TSBR) layer, depending on the material of the active layer 36.

The active layer 36 may be disposed between the first and second semiconductor layers 31 and 320. The active layer 36 may include a single- or multi-quantum well structure material. In a case where the active layer 36 includes a material having a multi-quantum well structure, the active layer 36 may have a structure in which multiple quantum layers and multiple well layers are alternately stacked each other. The active layer 36 may emit light by combining electron-hole pairs in accordance with electrical signals applied thereto via the first and second semiconductor layers 31 and 32. For example, in a case where the active layer 36 emits blue-wavelength light, the quantum layers may include a material such as AlGaN or AlGaInN. For example, in a case where the active layer 36 has a multi-quantum well structure in which multiple quantum layers and multiple well layers are alternately stacked each other, the quantum layers may include a material such as AlGaN or AlGaInN, and the well layers may include a material such as GaN or AlInN. In an embodiment, in a case where the active layer 36 includes AlGaInN as its quantum layer(s) and AlInN as its well layer(s), the active layer 36 may emit blue light having a central wavelength range of about 450 nm to about 495 nm.

However, the disclosure is not limited to this. In another embodiment, the active layer 36 may have a structure in which a semiconductor material having a large band gap energy and a semiconductor material having a small band gap energy are alternately stacked each other or may include group-III or group-V semiconductor materials depending on the wavelength of light to be emitted. The type of light emitted by the active layer 36 is not particularly limited. The active layer 36 may emit light of a red or green wavelength range as necessary, instead of blue light. The active layer 36 may have a length of about 0.05 μm to about 0.10 μm, but the disclosure is not limited thereto.

Light may be emitted from the circumferential surface, in a lengthwise direction, of the light emitting element 30, and also from both sides of the light emitting element 30. The directionality of the light emitted from the active layer 36 is not particularly limited.

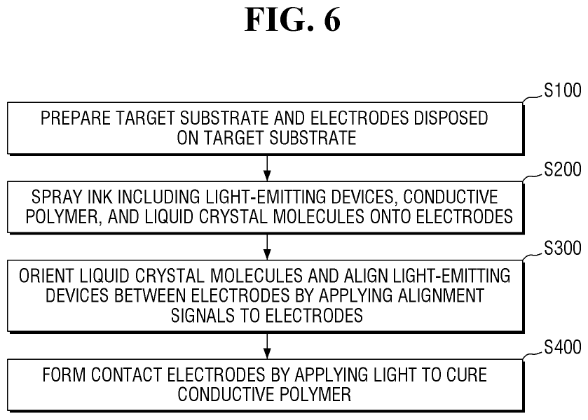

The electrode layer 37 may be an ohmic contact electrode, but the disclosure is not limited thereto. In another embodiment, the electrode layer 37 may be a Schottky contact electrode. The light emitting element 30 may include at least one electrode layer 37. The light emitting element 30 is illustrated as including one electrode layer 37, but the disclosure is not limited thereto. In another embodiment, the light emitting element 30 may include more than one electrode layer 37, or the electrode layer 37 may be omitted. The following description of the light emitting element 30 may also be applicable to a light emitting element 30 having more than one electrode layer 37 or having a different structure from the light emitting element 30 of FIGS. 5 and 6.

The electrode layer 37 may reduce the resistance between the light emitting element 30 and an electrode (or a contact electrode) in case that the light emitting element 30 is electrically connected to the electrode (or the contact electrode) in the display device 10. The electrode layer 37 may include a conductive metal. For example, the electrode layer 37 may include at least one of Al, Ti, In, Au, Ag, ITO, IZO, and ITZO. Also, the electrode layer 37 may include a semiconductor material doped with an n- or p-type dopant. Electrode layers 37 may include the same materials or different materials. The electrode layer 37 may have a length of about 0.05 μm to about 0.10 μm, but the disclosure is not limited thereto.

The insulating film 38 may be disposed to surround the outer surfaces of the above-described semiconductor layers and the above-described electrode layer. In an embodiment, the insulating film 38 may be disposed to surround at least the outer surface of the active layer 36 and may extend in the direction in which the light emitting element 30 extends. The insulating film 38 may protect other elements of the light emitting element 30. For example, the insulating film 38 may be formed to surround the sides of the other elements of the light emitting element 30, and may expose both end portions, in the lengthwise direction, of the light emitting element 30.

The insulating film 38 is illustrated as extending in the lengthwise direction of the light emitting element 30 to cover sides of the layers of the light emitting element 30, ranging from the first semiconductor layer 31 to the electrode layer 37, but the disclosure is not limited thereto. The insulating film 38 may cover the outer surfaces of only some of the semiconductor layers, including the active layer 36, or may cover only part of the outer surface of the electrode layer 37 to expose part of the outer surface of the electrode layer 37. Also, the insulating film 38 may have a round top surface near at least one end portion of the light emitting element 30.

The insulating film 38 may have a thickness of about 10 nm to about 1.0 μm, but the disclosure is not limited thereto. For example, the insulating film 38 may have a thickness of about 40 nm.

The insulating film 38 may include a material with insulating properties such as, for example, SiOₓ, SiNₓ, SiOₓNy, AlN, or Al₂O₃. The insulating film 38 may prevent any short circuit that may occur in case that the active layer 36 is placed in direct contact with electrodes that transmit electrical signals directly to the light emitting element 30. Also, since the insulating film 38 protects the outer surface of the light emitting element 30 including the active layer 36, any degradation in the emission efficiency of the light emitting element 30 may be prevented.

Also, in some embodiments, the outer surface of the insulating film 38 may be subjected to surface treatment. The light emitting element 30 may be sprayed on electrodes while being scattered in ink during the fabrication of the display device 10. The surface of the insulating film 38 may be hydrophobically or hydrophilically treated to keep the light emitting element 30 scattered in ink without agglomerating with other light emitting elements 30.

A length h of the light emitting element 30 may be in the range of about 1 μm to about 10 μm, about 2 μm to about 6 μm, or about 3 μm to about 5 μm. Also, the diameter of the light emitting element 30 may be in the range of about 30 nm to about 700 nm, and the aspect ratio of the light emitting element 30 may be about 1.2 to about 100. However, the disclosure is not limited to this. Multiple light emitting elements 30 included in the display device 10 may have different diameters depending on the composition of their respective active layers 36. For example, the diameter of the light emitting element 30 may be about 500 nm.

A method of manufacturing the display device 10 will hereinafter be described.

As described above, during the fabrication of the display device 10, the light emitting elements 30 may be sprayed onto the electrodes (21 and 22) in a state of being dispersed in ink together with conductive polymer. Also, liquid crystal molecules may be dispersed in the ink to properly align the light emitting elements 30. During the fabrication of the display device 10, the liquid crystal molecules may also be oriented (or aligned) in a direction by an electric field for aligning the light emitting elements 30. The light emitting elements 30 may be disposed with a high degree of alignment between the electrodes (21 and 22) by being affected by the alignment of the liquid crystal molecules, while being seated on the electrodes (21 and 22) by the electric field.

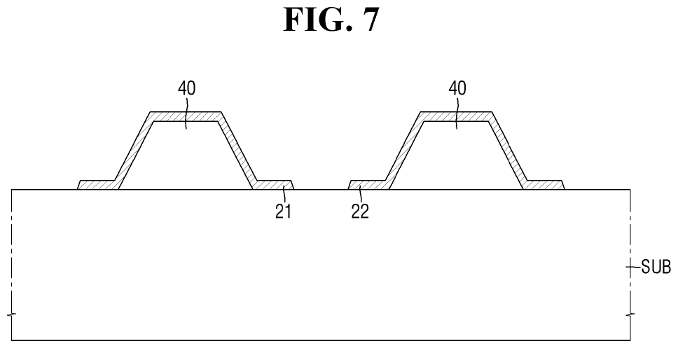

FIG. 6 is a flowchart illustrating a method of manufacturing a display device according to an embodiment of the disclosure. FIGS. 7 through 12 are schematic cross-sectional views illustrating the method of manufacturing a display device according to an embodiment of the disclosure.

Referring to FIG. 6, the method of manufacturing the display device 10 may include preparing a target substrate SUB and disposing multiple electrodes (21 and 22) on the target substrate SUB (S100), spraying ink S including light emitting elements 30, conductive polymer PM, and liquid crystal molecules LC onto the electrodes (21 and 22) (S200), aligning the liquid crystal molecules LC and aligning the light emitting elements 30 between the electrodes (21 and 22) by applying alignment signals to the electrodes (21 and 22) (S300), and forming contact electrodes (26 and 27) by applying light and curing the conductive polymer PM (S400). Not only the light emitting elements 30 and the conductive polymer PM for forming the contact electrodes (26 and 27), but also the liquid crystal molecules LC may be dispersed in the ink S sprayed onto the target substrate SUB.

The alignment signals applied to the electrodes (21 and 22) may generate an electric field E on the target substrate SUB, and the light emitting elements 30 and the liquid crystal molecules LC may be aligned in a direction by the electric field E. The light emitting elements 30 may be affected by the alignment of the liquid crystal molecules LC, receiving an electric force from the electric field E. The light emitting elements 30 may be aligned along the direction in which the liquid crystal molecules LC are aligned, and the degree of alignment of the light emitting elements 30 between the electrodes (21 and 22) may be improved.

The fabrication of the display device 10 will hereinafter be described. Referring to FIG. 7, the target substrate SUB may be prepared, and the electrodes (21 and 22) may be formed on the target substrate SUB. The electrodes (21 and 22) may include first and second electrodes 21 and 22, which are spaced apart from, and face each other. Also, as already mentioned above, multiple first banks 40 may be also disposed between the first and second electrodes 21 and 22 and the target substrate SUB. Although not specifically illustrated, the target substrate SUB may include a first substrate 11 and multiple circuit elements, which are formed by multiple conductive layers and multiple insulating layers. For convenience, the first substrate 11 and the circuit elements are simply illustrated and described as the target substrate SUB.

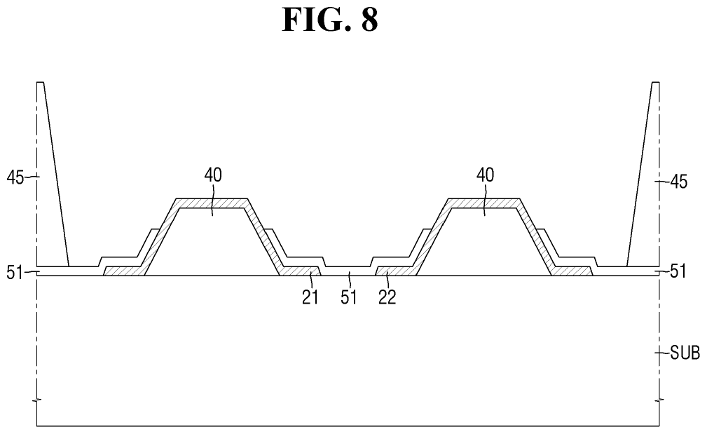

Thereafter, referring to FIG. 8, a first insulating layer 51 and a second bank 45, which partially cover the first and second electrodes 21 and 22, may be formed. The first insulating layer 51 may be disposed on the entire surface of the target substrate SUB to expose portions of the top surfaces of the electrodes (21 and 22). The second bank 45 may be disposed on the first insulating layer 51 to surround a region where the electrodes (21 and 22) are disposed.

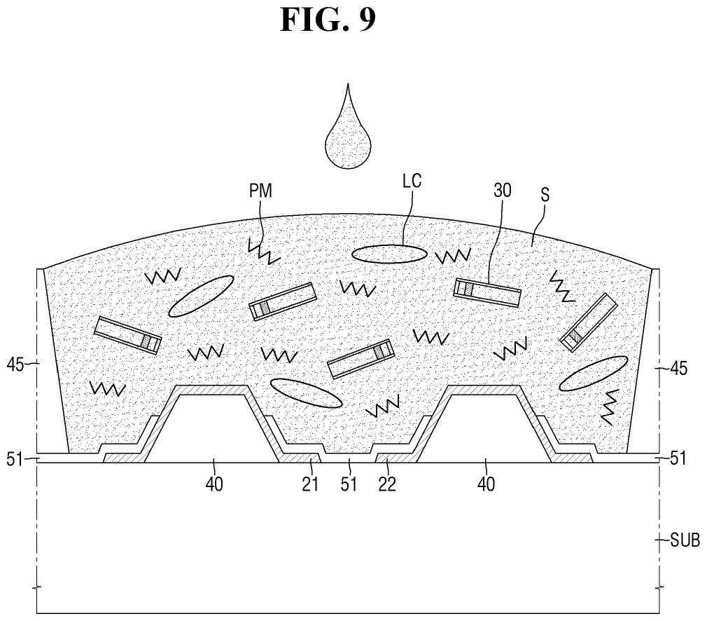

Thereafter, referring to FIG. 9, ink S having light emitting elements 30, liquid crystal molecules LC, and conductive polymer PM dispersed therein may be sprayed onto the target substrate SUB. In an embodiment, the light emitting elements 30 may be prepared in a state of being dispersed in the ink together with the liquid crystal molecules LC and the conductive polymer PM and may be sprayed onto the target substrate SUB by an inkjet printing device (not illustrated) through a printing process, but the disclosure is not limited thereto. In another embodiment, the ink S may be sprayed onto the target substrate SUB through a slit process. The ink S may include a solvent and the light emitting elements, the liquid crystal molecules LC, and the conductive polymer PM, which are dispersed in the solvent, may be provided in the form of a solution or a colloid. For example, the solvent may be acetone, water, alcohol, toluene, propylene glycol (PG), or propylene glycol methyl acetate (PGMA), but the disclosure is not limited thereto.

The light emitting elements 30 are as described above. The light emitting elements 30 may be seated between the electrodes (21 and 22) by alignment signals applied to the electrodes (21 and 22). For example, in response to alignment signals being applied to the first and second electrodes 21 and 22, an electric field may be generated in the ink sprayed onto the electrodes (21 and 22). Once an electric field is generated on the first and second electrodes 21 and 22, the light emitting elements 30 dispersed in ink may receive a dielectrophoretic force. The light emitting elements 30 receiving a dielectrophoretic force may be seated between the first and second electrodes 21 and 22 with their orientation (or alignment direction) directions and locations changing.

The conductive polymer PM may be cured later and may thus form contact electrodes (26 and 27). The conductive polymer PM may include a polymer chain and may have a molecular structure extending in a direction, like the light emitting elements 30. Even in the case of the conductive polymer PM, the direction in which the polymer chain extends may be oriented (or aligned) in a particular direction by the electric field formed in the ink S.

The liquid crystal molecules LC may also be aligned in a direction by the electric field formed in the ink S. In an embodiment, the liquid crystal molecules LC may have positive dielectric anisotropy, and the liquid crystal molecules LC may be aligned with the direction of the electric field generated in the ink S. The light emitting elements 30 may be oriented (or aligned) in a direction by the electric field generated on the electrodes (21 and 22) and may be affected by the liquid crystal molecules LC aligned in the ink S. The light emitting elements 30 may be aligned with the liquid crystal molecules LC by an electric field and may thus be disposed with a higher degree of alignment between the electrodes (21 and 22).

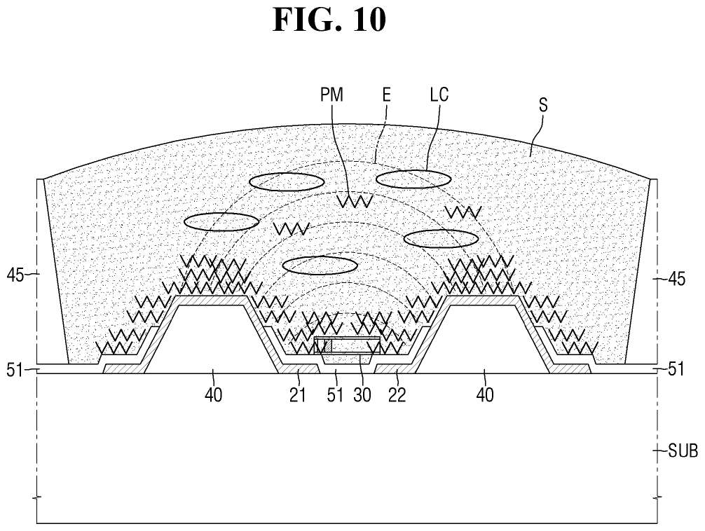

Referring to FIG. 10, an electric field E may be generated on the ink S by applying alignment signals to the electrodes (21 and 22) to align the light emitting elements 30 and the liquid crystal molecules LC and to arrange the light emitting elements 30 between the electrodes (21 and 22). Each of the light emitting elements 30 may include a semiconductor layer doped with an n- or p-type dopant and may thus have dipole moments. The light emitting elements 30 may receive a dielectrophoretic force from the electric field E formed in the ink S and may thus be aligned between the electrodes (21 and 22). As the orientation directions and locations of the light emitting elements 30 are changed by the dielectrophoretic force, the light emitting elements 30 may be disposed such that first and second end portions of each of the light emitting elements 30 may be placed on the first and second electrodes 21 and 22, respectively. The light emitting elements 30 may be aligned between the electrodes (21 and 22) along the direction in which the electrodes (21 and 22) extend.

The liquid crystal molecules LC may be dispersed in the ink S and may be oriented by the electric field E such that the direction in which the liquid crystal molecules LC extend may face a direction. As described above, as the liquid crystal molecules LC have positive dielectric anisotropy, the liquid crystal molecules LC may be oriented such that the direction in which the liquid crystal molecules LC extend may face the direction in which the electric field E is formed. The liquid crystal molecules LC and the light emitting elements 30 may both extend in a direction and may have a particular orientation direction. As the light emitting elements 30 are disposed between the electrodes (21 and 22) in a state of being dispersed in the ink S, the alignment of the light emitting elements 30 may be affected by the orientation direction of the liquid crystal molecules LC. The liquid crystal molecules LC may be oriented in the direction of the electric field E, i.e., the direction in which the first and second electrodes 21 and 22 extend, and the light emitting elements 30 may be aligned by the oriented liquid crystal molecules LC such that the direction in which the light emitting elements 30 extend may coincide with the direction in which the liquid crystal molecules LC extend. The light emitting elements 30 may be disposed such that both end portions thereof may be placed on the first and second electrodes 21 and 22 in a state that the direction in which the light emitting elements 30 extend is oriented in the direction in which the first and second electrodes 21 and 22 are spaced apart from each other. The light emitting elements 30 may be uniformly aligned between the electrodes (21 and 22) and may have a high degree of alignment between the electrodes (21 and 22), as compared to the case that no liquid crystal molecules LC are provided.

The conductive polymer PM included in the ink S may be oriented, together with the liquid crystal molecules LC, by the electric field E. The main chain portion of the polymer chain of the conductive polymer PM may be oriented along the direction in which the liquid crystal molecules LC are oriented. The conductive polymer PM may agglomerate on the electrodes (21 and 22) where the electric field E is generated, and even on both end portions of each of the light emitting elements 30 on the electrodes (21 and 22). The conductive polymer PM may be dispersed in the ink S, may agglomerate on the electrodes (21 and 22), together with the light emitting elements 30, and may fix the locations of the light emitting elements 30 aligned between the electrodes (21 and 22).

The initial alignment locations of the light emitting elements 30 may change in case that contact electrodes (26 and 27) are formed after the alignment of the light emitting elements 30 between the electrodes (21 and 22). The orientation directions or the locations of some of the light emitting elements 30 may change between the electrodes (21 and 22) so that the corresponding light emitting elements 30 may not be electrically connected to the electrodes (21 and 22) through the contact electrodes (26 and 27). However, as the contact electrodes (26 and 27) of the display device 10 include the conductive polymer PM, the light emitting elements 30 may be aligned between the electrodes (21 and 22) and may be fixed using the conductive polymer PM. As a result, a separate member or process for fixing the alignment locations of the light emitting elements 30 may not be needed, and the alignment of the light emitting elements 30 and the formation of the contact electrodes (26 and 27) may be performed by substantially the same process.

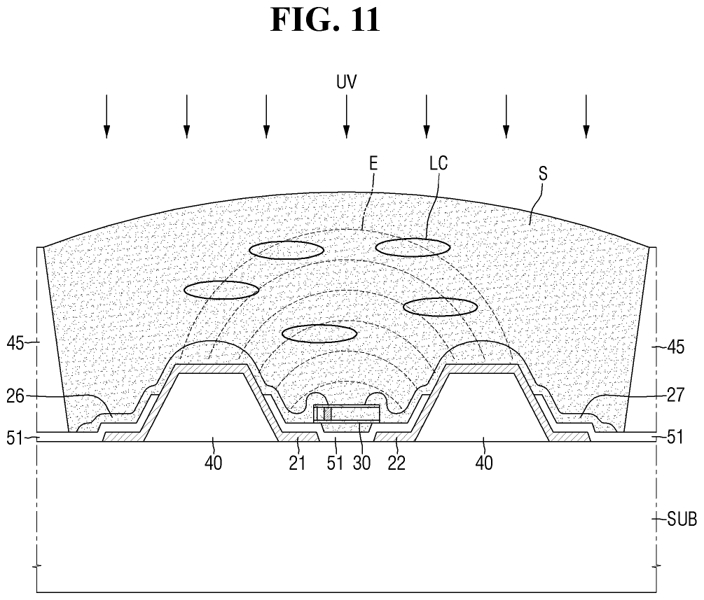

Thereafter, referring to FIG. 11, the contact electrodes (26 and 27) may be formed by applying light UV onto the target substrate SUB to cure the agglomerated conductive polymer PM. The light UV may be light typically irradiated for curing conductive polymer PM. In an embodiment, the light UV may be ultraviolet (UV) light, but the disclosure is not limited thereto.

The conductive polymer PM agglomerated on the electrodes (21 and 22) and both end portions of each of the light emitting elements 30 may be cured by the light UV and may thus form the contact electrodes (26 and 27). The conductive polymer PM may agglomerate at different densities depending on the height on the electrodes (21 and 22) where the electric field E is generated. For example, the conductive polymer PM may agglomerate at a highest density on portions of the electrodes (21 and 22) that have a greatest height due to the presence of the first banks 40 and at a lower density on portions of the electrodes (21 and 22) that are disposed directly on the target substrate SUB. As a result, the contact electrodes (26 and 27) may have different thicknesses from one location to another location.

The conductive polymer PM may form the contact electrodes (26 and 27) and may fix the light emitting elements 30. In some embodiments, the irradiation of the light UV for curing the conductive polymer PM and the generation of the electric field E for aligning the light emitting elements 30 may be performed at the same time. In an embodiment, the light emitting elements 30 may be fixed by generating the electric field E on the ink S to orient the liquid crystal molecules LC and applying the light UV with the light emitting elements 30 aligned to cure the conductive polymer PM. In this step, the contact electrodes (26 and 27) may be formed with the alignment locations of the light emitting elements 30 fixed.

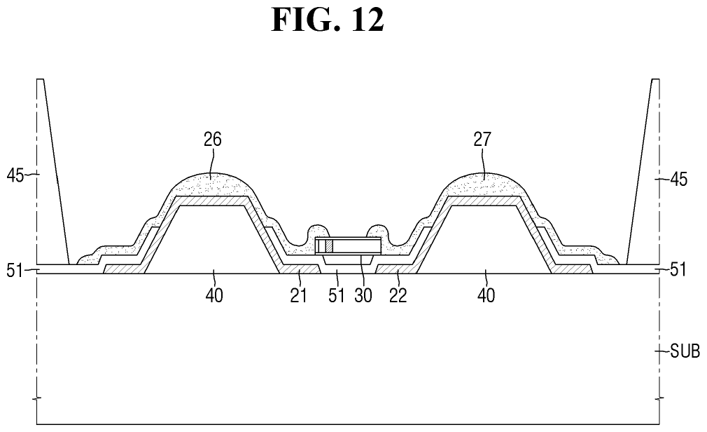

Thereafter, referring to FIG. 12, the solvent of the ink S and the liquid crystal molecules LC may be removed. Also, although not specifically illustrated, a second insulating layer 52, which covers the contact electrodes (26 and 27) and the light emitting elements 30, may be formed, thereby obtaining the display device 10.

By orienting the liquid crystal molecules LC and the light emitting elements 30 together, the light emitting elements 30 may be uniformly aligned. Also, any changes in the alignment locations of the light emitting elements 30 may be prevented by using the conductive polymer PM, which forms the contact electrodes (26 and 27) and fixes the light emitting elements 30. Accordingly, the number of fabrication processes for the display device 10 may be reduced, and the degree of alignment of the light emitting elements 30 may be improved.

Various other embodiments of the display device 10 will hereinafter be described.

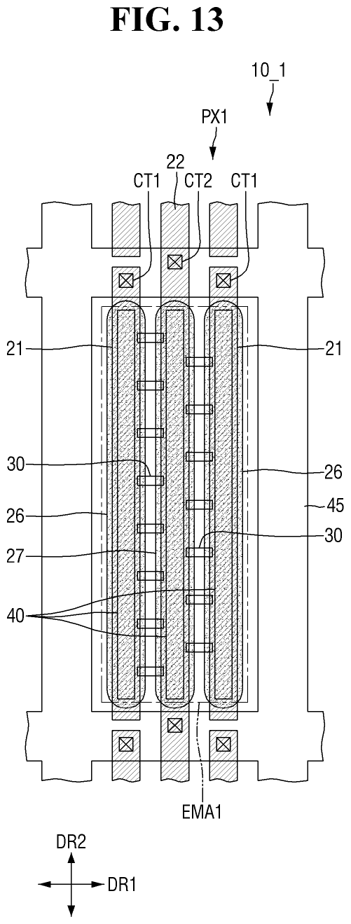

FIG. 13 is a plan view of a subpixel of a display device according to another embodiment of the disclosure.

Referring to FIG. 13, a display device 101 may include numbers of electrodes (21 and 22), first banks 40, and contact electrodes (26 and 27). Each subpixel PXn of the display device 10_1 may include multiple first electrodes 21 and at least one second electrode 22, which is disposed between the first electrodes 21. The first electrodes 21 and the second electrode 22 may be disposed to be spaced apart from and face one another in a first direction DR1 and may be alternately arranged along the first direction DR1, in each subpixel PXn. As the number of electrodes (21 and 22) disposed in each subpixel PXn increases, more first banks 40 may be disposed on a first planarization layer 19, and more contact electrodes (26 and 27) may be disposed on the electrodes (21 and 22). FIG. 13 illustrates that as two first electrodes 21 and one second electrode 22 are disposed in each subpixel PXn of the display device 10_1, three first banks 40, two first contact electrodes 26, and one second contact electrode 27 are disposed, but the disclosure is not limited thereto. The numbers of first banks 40, electrodes (21 and 22), and contact electrodes (26 and 27) may further increase.

As the number of light emitting elements 30 disposed between the first electrodes 21 and the second electrode 22 of the display device 10_1 increases, the amount of light emitted by each unit pixel PX or each subpixel PXn may increase.

Each of the first electrodes 21 may be in contact with a first conductive pattern CDP through a first contact hole CT1 and may thus be electrically connected to a driving transistor DT. Light emitting elements 30 disposed between one of the first electrodes 21 and the second electrode 22 may form parallel connections with light emitting elements 30 disposed between the other first electrode 21 and the second electrode 22, but the disclosure is not limited thereto. In some embodiments, the display device 10 may further include electrodes that are not directly connected to circuit elements disposed below the first planarization layer 19, and light emitting elements 30 disposed between the electrodes may form serial connections.

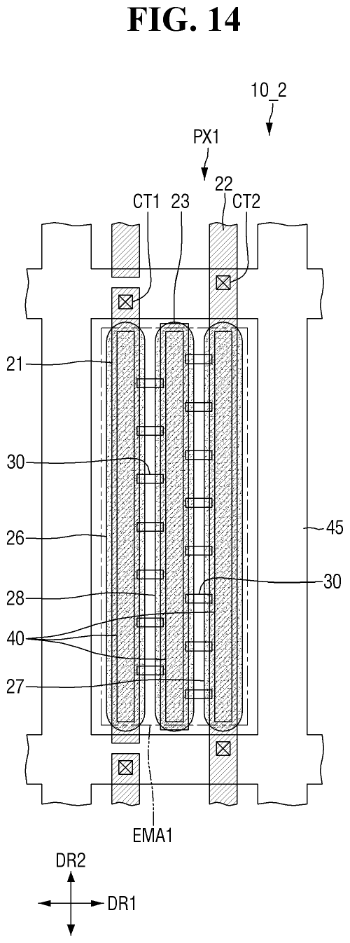

FIG. 14 is a plan view of a subpixel of a display device according to another embodiment of the disclosure.

Referring to FIG. 14, a display device 102 may include first and second electrodes 21 and 22 and may further include a third electrode 23, which is disposed between the first and second electrodes 21 and 22. Also, contact electrodes (26, 27, and 28) may further include a third contact electrode 28, which is disposed on the third electrode 23. A first bank 40 may be also disposed between the third electrode 23 and a first planarization layer 19, and light emitting elements 30 may be disposed between the first and third electrodes 21 and 23 and between the third and second electrodes 23 and 22. The display device 10_2 differs from the embodiment of FIG. 2 in that each subpixel PXn further includes the third electrode 23 and the third contact electrode 28. The third electrode 23 will hereinafter be described.

The third electrode 23 may be disposed between the first and second electrodes 21 and 22. Multiple first banks 40, for example, three first banks 40, may be disposed on the first planarization layer 19, and the first, third, and second electrodes 21, 23, and 22 may be sequentially arranged on the respective first banks 40. The third electrode 23 may extend in a second direction DR2. The third electrode 23, unlike the first and second electrodes 21 and 22, may extend in the second direction DR2, but may be disposed to not overlap, but be spaced apart from, portions of a second bank 45 extending in a first direction DR1. For example, the length, in the second direction DR2, of the third electrode 23 may be less than the length of the first and second electrodes 21 and 22, and the third electrode 23 may be disposed not to extend beyond the boundaries between neighboring subpixels PXn.

The light emitting elements 30 may be disposed between the first and third electrodes 21 and 23 and between the third and second electrodes 23 and 22. The third contact electrode 28 may have the same shape as first and second contact electrodes 26 and 27 and may be disposed on the third electrode 23. For example, the third contact electrode 28 may include conductive polymer.

Light emitting elements 30 disposed between the first and third electrodes 21 and 23 may be in contact with the first and third contact electrodes 26 and 28 and may thus be electrically connected to the first and third electrodes 21 and 23. Light emitting elements 30 disposed between the third and second electrodes 23 and 22 may be in contact with the third and second contact electrodes 28 and 27 and may thus be electrically connected to the third and second electrodes 22 and 22.

The third electrode 23, unlike the first and second electrodes 21 and 22, may not be directly connected to a circuit element layer through a contact hole. Electrical signals applied to the first and second electrodes 21 and 22 may be transmitted to the third electrode 23 through the first and second contact electrodes 26 and 27 and the light emitting elements 30. For example, the light emitting elements 30 disposed between the first and third electrodes 21 and 23 may form serial connections with the light emitting elements 30 disposed between the third and second electrodes 23 and 22. As the display device 10_2 further includes the third electrode 23, serial connections between the light emitting elements 30 may be configured, and the emission efficiency of each subpixel PXn may be further improved.

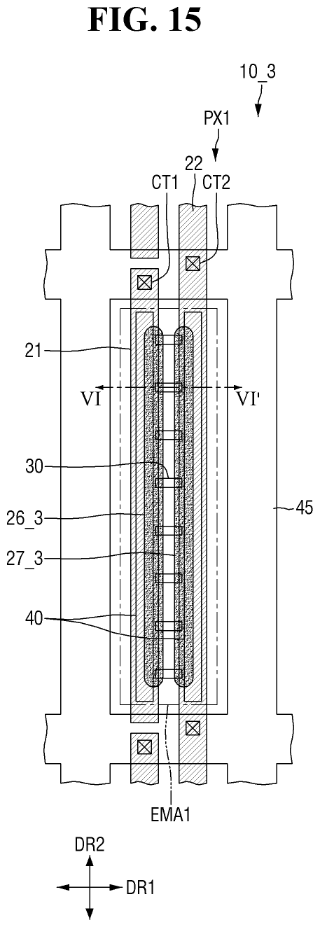

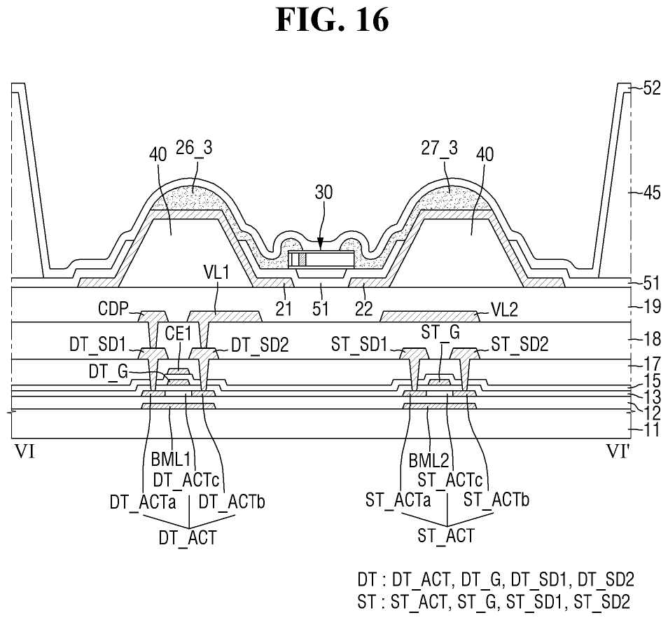

FIG. 15 is a plan view of a subpixel of a display device according to another embodiment of the disclosure. FIG. 16 is a schematic cross-sectional view taken along line VI-VI′ of FIG. 15.

Referring to FIGS. 15 and 16, in a display device 103, the width of contact electrodes (26_3 and 27_3) may be less than the width of electrodes (21 and 22). The contact electrodes (26_3 and 27_3) may be disposed on portions of the top surfaces of the electrodes 21 and 22 that are exposed due to the absence of a first insulating layer 51 thereon. For example, a first contact electrode 26_3 may be disposed to be in contact with first end portions of light emitting elements 30 and part of the top surface of a first electrode 21 and to cover only one side of the first electrode 21 that faces a second electrode 22. A second contact electrode 273 may be disposed to be in contact with second end portions of light emitting elements 30 and part of the top surface of a second electrode 22 and to cover only one side of the second electrode 22 that faces the first electrode 21.

The width of the contact electrodes (26_3 and 27_3) may be controlled during the agglomeration of conductive polymer PM on the electrodes (21 and 22) and the light emitting elements 30. As described above, in case that an electric field E is generated on ink S to orient liquid crystal molecules LC and the light emitting elements 30, the main chain portion of the polymer chain of the conductive polymer PM may also be oriented in a direction so that the conductive polymer PM may agglomerate. Here, if the electric field E is strong in the spaces between the light emitting elements 30 and the electrodes (21 and 22), the conductive polymer PM may agglomerate intensely. As a result, the conductive polymer PM may agglomerate on the light emitting elements 30 and on the sides of the electrodes (21 and 22) to form the contact electrodes (26_3 and 273), and the contact electrodes (26_3 and 273) may have a relatively small width. The embodiment of FIG. 14 differs from the embodiment of FIGS. 2 and 3 in the width of the contact electrodes (26_3 and 273), and descriptions of any redundant features will be omitted.

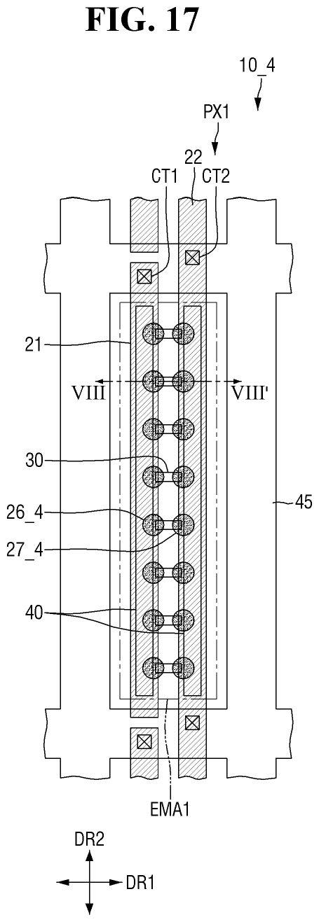

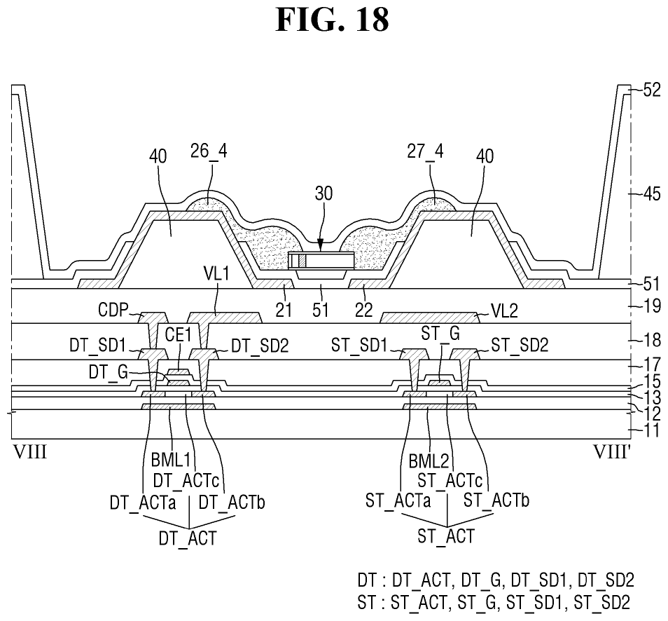

FIG. 17 is a plan view of a subpixel of a display device according to another embodiment of the disclosure. FIG. 18 is a schematic cross-sectional view taken along line VIII-VIII′ of FIG. 17.

Referring to FIGS. 17 and 18, in a display device 10_4, contact electrodes (26_4 and 27_4) may be disposed only on portions of electrodes (21 and 22) where light emitting elements 30 are disposed. The contact electrodes (26_4 and 27_4) may not extend in a direction and may be disposed to be spaced apart from one another to correspond to the portions of the electrodes (21 and 22) where the light emitting elements 30 are disposed. As a result, the contact electrodes (26_4 and 27_4) may form island patterns in each subpixel PXn. The embodiment of FIGS. 17 and 18 differs from the previous embodiments in the arrangement and the shape of the contact electrodes (26_4 and 27_4).

As described above, in case that an electric field E is generated on ink S, liquid crystal molecules LC and the light emitting elements 30 may be oriented, and conductive polymer PM may agglomerate on the electrodes (21 and 22) and the light emitting elements 30. Here, the conductive polymer PM may agglomerate affected by the light emitting elements 30, which are aligned affected by the orientation direction of the liquid crystal molecules LC. In case that the light emitting elements 30 are disposed on the electrodes (21 and 22) by the electric field E, the conductive polymer PM may agglomerate on both end portions of each of the light emitting elements 30. Accordingly, the conductive polymer PM may agglomerate mainly on both end portions of each of the light emitting elements 30 and portions of the electrodes (21 and 22) on sides of first banks 40, and the contact electrodes (26_4 and 27_4) may be disposed to correspond to portions of the electrodes (21 and 22) where both end portions of each of the light emitting elements 30 are placed. However, at least some of the conductive polymer PM may agglomerate on portions of the top surfaces of the electrodes 21 and 22 that are exposed due to the absence of a first insulating layer 51 thereon, and the contact electrodes (26_4 and 27_4) may be in contact with the electrodes (21 and 22).

Also, in some embodiments, the contact electrodes (26_4 and 27_4) may be thickest between both end portions of each of the light emitting elements 30 and portions of the electrodes (21 and 22) on the sides of the first banks 40. In a case where the conductive polymer PM is placed on the electrodes (21 and 22) by agglomerating on both end portions of each of the light emitting elements 30, a relatively large amount of conductive polymer PM may agglomerate near both end portions of each of the light emitting elements 30. As a result, the contact electrodes (26_4 and 27_4), which are formed by curing the conductive polymer PM, may be thickest on both end portions of each of the light emitting elements 30 and the portions of the electrodes (21 and 22) on the sides of the first banks 40, but the disclosure is not limited thereto.

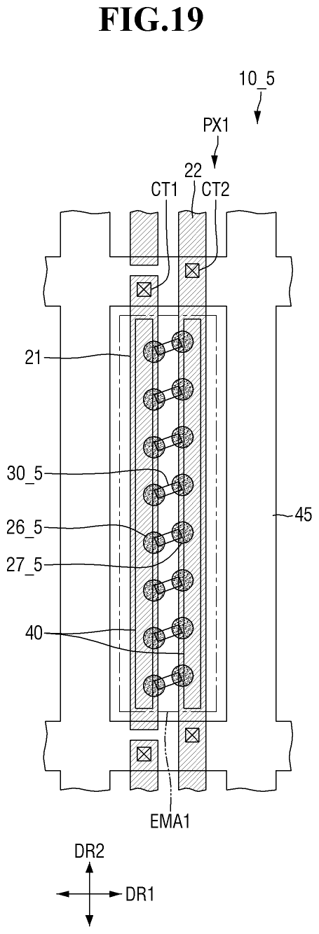

FIG. 19 is a plan view of a subpixel of a display device according to another embodiment of the disclosure.

Referring to FIG. 19, light emitting elements 30_5 may be arranged in a direction not perpendicular, but diagonal to a direction in which electrodes (21 and 22) extend. Accordingly, first contact electrodes 26_5 and second contact electrodes 27_5 may be spaced apart from one another in a direction between first and second directions DR1 and DR2. The embodiment of FIG. 19 differs from the embodiment of FIG. 17 in that the orientation direction of the light emitting elements 30_5 differs from the direction in which contact electrodes (26_5 and 27_5) are spaced apart from one another.

The light emitting elements 30_5 may be oriented together with liquid crystal molecules LC and may be affected by the orientation direction of the liquid crystal molecules LC. In some embodiments, the liquid crystal molecules LC may be oriented in a direction not perpendicular to the direction in which the electrodes (21 and 22) extend, and the light emitting elements 30_5 may be arranged in a diagonal direction with respect to the direction in which the electrodes (21 and 22) extend. The light emitting elements 30_5 may be aligned between first and second electrodes 21 and 22, but the orientation direction of the light emitting elements 305 may not be perpendicular to the arrangement direction of the light emitting elements 30_5. However, as the liquid crystal molecules LC are oriented in a uniform direction, the light emitting elements 30_5 may be aligned in a uniform direction.

Also, some of the light emitting elements 30_5 may be disposed such that only one end portion thereof may be placed on the electrodes (21 and 22). However, in a case where conductive polymer PM is disposed in a state of agglomerating on both end portions of each of the light emitting elements 30_5, the light emitting elements 30_5 may be electrically connected to the electrodes (21 and 22), even though they are oriented in the diagonal direction with respect to the direction in which the electrodes (21 and 22) extend. The contact electrodes (26_5 and 275) may be disposed to correspond to both end portions of each of the light emitting elements 30_5. As the contact electrodes (26_5 and 275) have a predetermined (or selectable) width, the contact electrodes (26_5 and 27_5) may be in contact with portions of the top surfaces of the electrodes (21 and 22). Even if one end portion of each of the light emitting elements 30_5 is not placed on the electrodes (21 and 22), the contact electrodes (26_5 and 275) may still be in contact with the corresponding end portion of each of the light emitting elements 305 and portions of the electrodes (21 and 22). Descriptions of other redundant features with the previous embodiments will be omitted.

The contact electrodes (26 and 27) may have a uniform thickness in areas covering the light emitting elements 30. In some embodiments, portions of the contact electrodes (26 and 27) covering the light emitting elements 30 may be greater than the diameter of the light emitting elements 30, and some of the light emitting elements 30 may be disposed at different heights in a cross-sectional view.

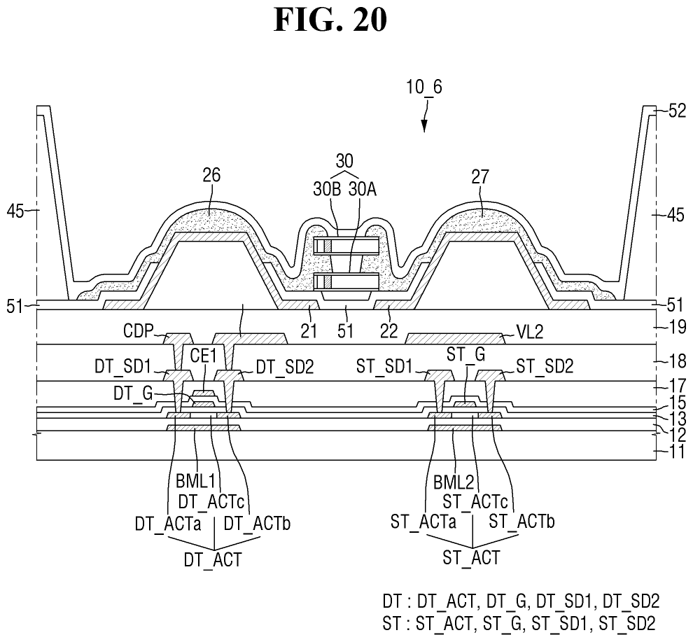

FIG. 20 is a plan view of a subpixel of a display device according to another embodiment of the disclosure.

Referring to FIG. 20, a display device 10_6 may include light emitting elements (30A and 30B), which are disposed at different heights. The light emitting elements 30 may be disposed such that both end portions thereof may be placed on electrodes (21 and 22), and may include first light emitting elements 30A, which are disposed directly on a first insulating layer 51, and second light emitting elements 30B, which are disposed on the first light emitting elements 30A.

The first light emitting elements 30A may be disposed directly on the first insulating layer 51. The first light emitting elements 30A may be the same as the light emitting elements 30 included in the display device 10.

The second light emitting elements 30B may be disposed on the first light emitting elements 30A, in a cross-sectional view, and may be positioned at a different height from the first light emitting elements 30A. Multiple light emitting elements 30 dispersed in ink S may be oriented by an electric field E and may thus be disposed on the electrodes (21 and 22). Here, conductive polymer PM may agglomerate on both end portions of each of the light emitting elements 30, and one or more light emitting elements 30 may be fixed by agglomeration of the conductive polymer PM. Some of the light emitting elements 30 may be disposed to overlap one another in a thickness direction. As the conductive polymer PM is cured to form contact electrodes (26 and 27), one or more light emitting elements 30 may be disposed to overlap one another in the thickness direction and may have different heights.

As multiple light emitting elements 30 are disposed to overlap one another in the thickness direction and are placed at different heights, more light emitting elements 30 may be arranged in each subpixel PXn. As a result, the amount of light emitted per unit area of each subpixel PXn of the display device 10_6 may be increased.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

1. A display device comprising:
a first electrode and a second electrode disposed on a substrate and spaced apart from each other;
a plurality of light emitting elements, at least a part of each of the plurality of light emitting elements being disposed between the first electrode and the second electrode;
a first contact electrode at least partially covering the first electrode, the first contact electrode electrically contacting first end portions of the plurality of light emitting elements; and
a second contact electrode spaced apart from the first contact electrode and at least partially covering the second electrode, the second contact electrode electrically contacting second end portions of the plurality of light emitting elements,
wherein the first contact electrode and the second contact electrode include conductive polymer.

2. The display device of claim 1, wherein the conductive polymer includes PEDOT:PSS.

3. The display device of claim 2, wherein each of the first contact electrode and the second contact electrode has a thickness in a range of about 150 nm to about 250 nm.

4. The display device of claim 2, wherein the first contact electrode and the second contact electrode are spaced apart from each other on the plurality of light emitting elements.

5. The display device of claim 1, further comprising:
a plurality of first banks disposed between the first electrode and the substrate and between the second electrode and the substrate, middle portions of the plurality of first banks being thicker than a rest of the plurality of first banks in a thickness direction,
wherein the first contact electrode and the second contact electrode are disposed to at least partially overlap one of the plurality of first banks in the thickness direction.

6. The display device of claim 5, wherein
the first contact electrode is disposed to overlap one of the plurality of first banks in the thickness direction,
the second contact electrode is disposed to overlap another one of the plurality of first banks in the thickness direction,
a portion of the first contact electrode that overlaps one of the thicker portions of the plurality of first banks is thicker than a rest of the first contact electrode, and
a portion of the second contact electrode that overlaps another one of the thicker portions of the plurality of first banks is thicker than a rest of the second contact electrode.

7. The display device of claim 5, wherein portions of the first contact electrode and the second contact electrode that cover the first end portions of the light emitting elements are thicker than the rest of the first contact electrode and the second contact electrode.

8. The display device of claim 6, wherein the plurality of light emitting elements include:
first light emitting elements whose including:
first end portions electrically contacting the first contact electrode; and
second end portions electrically contacting the second contact electrode; and
second light emitting elements, which are disposed on the first light emitting elements and including:
first end portions electrically contacting the first contact electrode; and
second end portions electrically contacting the second contact electrode.

9. The display device of claim 1, further comprising:
a first insulating layer disposed on the substrate between the first electrode and the second electrode, partially covering the first electrode and the second electrode,
wherein the plurality of light emitting elements are disposed on the first insulating layer.

10. The display device of claim 9, further comprising:
a second insulating layer disposed on the substrate covering the first electrode, the second electrode, the plurality of light emitting elements, the first contact electrode, and the second contact electrode.

11. The display device of claim 10, wherein
the second insulating layer is directly contacting portions of outer surfaces of the plurality of light emitting elements, and
the first contact electrode and the second contact electrode are spaced apart from each other with the portions of the outer surfaces of the plurality of light emitting elements disposed between the first and second contact electrodes.

12. The display device of claim 10, further comprising:
a second bank disposed on the substrate surrounding a region where the plurality of light emitting elements are disposed,
wherein the second insulating layer is disposed on the second bank.

13. A method of manufacturing a display device, comprising:
preparing substrate and disposing a first electrode and a second electrode on the substrate;
spraying ink including a plurality of light emitting elements, liquid crystal molecules, and conductive polymer onto the substrate; and
forming a plurality of contact electrodes disposed on the first electrode and the second electrode by aligning the liquid crystal molecules and the plurality of light emitting elements by generating an electric field on the substrate and curing the conductive polymer.

14. The method of claim 13, wherein
the plurality of light emitting elements and the liquid crystal molecules extend in a first direction, and
the forming of the plurality of contact electrodes comprises aligning the plurality of light emitting elements and the liquid crystal molecules such that the first direction in which the plurality of light emitting elements and the liquid crystal molecules extend is parallel to an upper surface of the substrate.

15. The method of claim 14, wherein the liquid crystal molecules have positive dielectric anisotropy.

16. The method of claim 14, wherein
the conductive polymer is aligned by the electric field such that a main chain portion thereof are aligned in a second direction and agglomerates on the first electrode and the second electrode, and
both end portions of the plurality of light emitting elements are fixed by the conductive polymer, aligned in the second direction.

17. The method of claim 16, wherein the conductive polymer includes PEDOT:PSS.

18. The method of claim 16, wherein the curing of the conductive polymer is performed by applying light while the plurality of light emitting elements and the liquid crystal molecules are aligned in the second direction.

19. The method of claim 16, wherein the plurality of light emitting elements include:
first light emitting elements including;
first end portions disposed on the first electrode, and
second end portions disposed on the second electrode, and
second light emitting elements which are disposed on the first light emitting elements and including:
first end portions disposed on the first electrode; and
second end portions disposed on the second electrode.

20. The method of claim 19, wherein the plurality of contact electrodes include:
a first contact electrode electrically contacting first end portions of the plurality of light emitting elements and the first electrode; and
a second contact electrode electrically contacting second end portions of the plurality of light emitting elements and the second electrode, the second contact electrode being spaced apart from the first contact electrode.
